(19) United States
(12) Patent Application Publication
(10) Pub. No.: US 2026/0143651 A1
(43) Pub. Date: May 21, 2026

(54) DATA CENTER HVAC SYSTEM WITH RACK LEVEL AIR FLOW CONTROL

(71) Applicant: Tyco Fire & Security GmbH, Neuhausen am Rheinfall (CH)

(72) Inventors: Subrata Bhattacharya, Singapore (SG); Sanjay Rajak, Kolkata (IN); Manish Parte, Pune (IN); Subramaniam Subbiah, Subang Jaya (MY)

(21) Appl. No.: 19/396,073

(22) Filed: Nov. 20, 2025

(30) Foreign Application Priority Data
Nov. 21, 2024 (IN) 202441090506
Jan. 2, 2025 (SG) 10202500005P
Jan. 2, 2025 (SG) 10202500006Y
Jan. 2, 2025 (SG) 10202500007U
Jan. 2, 2025 (SG) 10202500008X

(51) Int. Cl. H05K 7/20

(52) U.S. Cl. CPC H05K 7/20836; H05K 7/20736

(57) ABSTRACT

A system for monitoring and controlling a data center is described. The system includes a damper configured to adjust a resistance to air flowing through a computer rack. The system controls an air temperature exiting the computer rack by adjusting the damper of the computer rack to a position based at least upon a measured value of the air temperature exiting the computer rack and a setpoint for the air temperature exiting the computer rack. The temperature sensor can be rack-mounted or there may be a multiplicity of sensors in order to reduce measurement inaccuracies caused by airflow gradients in the computer rack. The amount of heat transferred to the air flowing through the computer rack can be used to provide feedforward control. The system can be configured to open the damper in response to a failure (e.g., control failure or power failure).

### CROSS-REFERENCE TO RELATED PATENT APPLICATIONS

This application claims priority to India Provisional Patent Application No. 202441090506 filed on Nov. 21, 2024, Singapore Provisional Patent application Ser. No. 10202500005P filed on Jan. 2, 2025, Singapore Provisional Patent application Ser. No. 10202500006Y filed on Jan. 2, 2025, Singapore Provisional Patent application Ser. No. 10202500007U filed on Jan. 2, 2025, and Singapore Provisional Patent Application 10202500008X filed on Jan. 2, 2025, each of which is herein incorporated by reference in its entirety.

### BACKGROUND

The present disclosure relates generally to building management systems. The present disclosure relates more particularly to providing cooling to computer racks in data centers.

A building management system (BMS) is, in general, a system of devices configured to control, monitor, and manage equipment in or around a building or building area. A BMS can include a heating, ventilation, or air conditioning (HVAC) system, a security system, a lighting system, a fire alerting system, another system that is capable of managing building functions or devices, or any combination thereof. BMS devices may be installed in any environment (e.g., an indoor area or an outdoor area) and the environment may include any number of buildings, spaces, zones, rooms, or areas. A BMS may include METASYS® building controllers or other devices sold by Johnson Controls, Inc., as well as building devices and components from other sources.

A BMS may include one or more computer systems (e.g., servers, BMS controllers, etc.) that serve as enterprise level controllers, application or data servers, head nodes, master controllers, or field controllers for the BMS. Such computer systems may communicate with multiple downstream building systems or subsystems (e.g., an HVAC system, a security system, etc.) according to like or disparate protocols (e.g., LON, BACnet, etc.). The computer systems may also provide one or more human-machine interfaces or client interfaces (e.g., graphical user interfaces, reporting interfaces, text-based computer interfaces, client-facing web services, web servers that provide pages to web clients, etc.) for controlling, viewing, or otherwise interacting with the BMS, its subsystems, and devices.

Operations of computers in a data center generate significant heat, and cooling is essential for maintaining operations. Data centers can account for as much as 2% of the global energy, an amount that is expected to double over the next few years. A significant portion of the energy used by data centers can be traced to providing cooling to the computers necessitating advanced control techniques to limit energy usage. BMS systems may be used control the cooling provided to the computers, server racks, etc. of a data center.

### SUMMARY

An embodiment of the present disclosure relates to a system for monitoring and controlling a data center. The system includes a damper configured to adjust a resistance to air flowing through a computer rack and one or more memory devices having instructions stored thereon that, when executed by one or more processors, cause the one or more processors to perform operations including controlling an air temperature exiting the computer rack by adjusting the damper of the computer rack to a position based at least upon a measured value of the air temperature exiting the computer rack and a setpoint for the air temperature exiting the computer rack.

In some embodiments, the operations also include estimating an amount of heat transferred to the air flowing through the computer rack using the measured value of the air temperature exiting the computer rack, wherein the position is based at least upon the estimated amount of heat transferred to the air.

In some embodiments, the operations also include calculating a cooling utilization index based on the estimated amount of heat transferred to the air flowing through the computer rack, the cooling utilization index indicative of a fraction of cooling capacity provided to the computer rack to a total cooling capacity that can be provided to the computer rack and adjusting parameters of a control strategy for controlling the air temperature exiting the computer rack based on the cooling utilization index.

In some embodiments, the total cooling capacity that can be provided to the computer rack is based on at least one of a maximum air flow through the computer rack or a maximum outlet air temperature of the computer rack.

In some embodiments, the total cooling capacity that can be provided to the computer rack is based on at least one of a maximum outlet air temperature of the computer rack or a minimum outlet air temperature of HVAC equipment supplying cooled air to the computer rack.

In some embodiments, the damper is configured to open in response to a failure or the operations further including opening the damper in response to a failure.

In some embodiments, controlling the air temperature exiting the computer rack includes executing a control algorithm with at least a proportional term and an integral term.

In some embodiments, controlling the air temperature exiting the computer rack includes providing feedforward control based on an estimated amount of heat transferred to the air flowing through the computer rack.

In some embodiments, controlling the air temperature exiting the computer rack also includes predicting the amount of heat transferred into the air flowing through the computer rack and providing the feedforward control based on the predicted amount of heat transferred.

Another aspect of the present disclosure relates to a method for monitoring and controlling a data center. The method includes estimating an amount of heat transferred to air flowing through a computer rack using a measured temperature of the air exiting the computer rack and controlling an air temperature exiting the computer rack by adjusting a damper to a position based at least upon the estimated amount of heat transferred to the air flowing through the computer rack.

The method also includes calculating a cooling utilization index based on the estimated amount of heat transferred to the air flowing through the computer rack, the cooling utilization index indicative of a fraction of cooling capacity provided to the computer rack to a total cooling capacity that can be provided to the computer rack and adjusting parameters of a control strategy for controlling the air temperature exiting the computer rack based on the cooling utilization index.

In some embodiments, the total cooling capacity that can be provided to the computer rack is based on at least one of a maximum air flow through the computer rack or a maximum outlet air temperature of the computer rack.

In some embodiments, the total cooling capacity that can be provided to the computer rack is based on at least one of a maximum outlet air temperature of the computer rack or a minimum outlet air temperature of HVAC equipment supplying cooled air to the computer rack.

In some embodiments, the method also includes opening the damper in response to a failure.

In some embodiments, controlling the air temperature exiting the computer rack includes executing a control algorithm with at least a proportional term and an integral term.

In some embodiments, the method also includes selecting a setpoint for the air temperature exiting the computer rack or an air flow rate through the computer rack based on a health index of a computing device in the computer rack.

In some embodiments, the setpoint is selected below a threshold temperature at which the health index of the computing device no longer decreases.

Another aspect of the present disclosure relates to a cooling system for a computer rack. The cooling system includes a damper configured to attach to the computer rack and operable to adjust a resistance to air flowing through the computer rack, a temperature sensor configured to attach to the computer rack and measure the temperature of the air flowing through the computer rack as the air exits the computer rack, one or more memory devices having instructions stored thereon that, when executed by one or more processors, cause the one or more processors to perform operations including controlling an air temperature exiting the computer rack by adjusting the damper to a position based at least on a measurement from the temperature sensor.

In some embodiments, the operations also include calculating a cooling utilization index based at least on a measurement the temperature of the air flowing through the computer rack as it exits the computer rack, the cooling utilization index indicative of a fraction of cooling provided to the computer rack to a cooling capacity available to the computer rack.

In some embodiments, the operations also include calculating a server health index for one or more computers installed in the computer rack based on an integration over time when: (i) a temperature of the one or more computers is greater than a temperature threshold, (ii) a CPU usage of the one or more computers is greater than a CPU usage threshold, or (iii) a RAM usage of the one or more computers is greater than a RAM usage threshold.

This summary is illustrative and not intended to be limiting.

### BRIEF DESCRIPTION OF THE DRAWINGS

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

FIG. 1 is a drawing of a building equipped with a building management system (BMS), according to some embodiments.

FIG. 2 is a block diagram of a BMS that serves the building of FIG. 1, according to some embodiments.

FIG. 3 is a block diagram of a BMS controller which can be used in the BMS of FIG. 2, according to some embodiments.

FIG. 4 is another block diagram of the BMS that serves the building of FIG. 1, according to some embodiments.

FIG. 5 is a schematic illustration of a computer room air conditioning (CRAC) system cooling racks of computers in a data center, according to some embodiments.

FIG. 6A is an illustrative view of cooling in a data center using hot aisle containment, according to some embodiments.

FIG. 6B is an illustrative view of cooling in a data center using cold aisle containment, according to some embodiments.

FIG. 7 is a block diagram of a BMS controller configured to control and monitor a data center, according to some embodiments.

FIG. 8A is an illustrative view of a rack for housing computers in a data center, according to some embodiments.

FIG. 8B is a floor plan showing the layout of sensors in racks of computers, according to some embodiments.

FIG. 9 is a flow of operations for initiating an automated action based on an estimated amount of transferred into the air from a rack of computers, according to some embodiments.

FIG. 10 is a flow of operations for initiating an automated action based on a predicted amount of transferred into the air from a rack of computers, according to some embodiments.

FIG. 11 is a flow of operations for controlling an air temperature exiting a rack by adjusting a damper position, according to some embodiments.

FIG. 12 is a flow of operations for initiating an automated action based on a server health index, according to some embodiments.

FIG. 13 is a flow of operations for initiating an automated action based an estimated remain lifetime of a computer, according to some embodiments.

FIG. 14 is a flow of operations for initiating an automated action based on a data center health index, according to some embodiments.

FIG. 15 is a schematic illustration of a computer room air conditioning (CRAC) system cooling racks of computers in a data center with an aspiration smoke detector disposed in an air duct, according to some embodiments.

### DETAILED DESCRIPTION

### Overview

Referring generally to the FIGURES, the techniques described herein can be applied with various cooling systems for data centers. For example, the techniques may be used when cooling is provided by direct evaporative cooling (DEC) units, computer room air conditioner (CRAC) systems, and/or computer room air handlers (CRAHs). Such systems are described in U.S. Pat. No. 9,635,786 (granted Apr. 25, 2017); U.S. Pat. No. 9,521,783 (granted Dec. 13, 2016); U.S. Pat. No. 11,767,992 (granted Sep. 26, 2023); U.S. Pat. No. 11,821,653 (granted Nov. 21, 2023); and/or U.S. Pat. No. 11,976,844 (granted May 5, 2024), the entire disclosures of which are incorporated by reference herein. Control and/or optimization of such systems is described in U.S. Patent Publication 2023/0354562 (published on Nov. 2, 2023), U.S. Patent Publication 2023/0349567 (published on Nov. 2, 2023), and P.C.T. Publication WO2023/212236 (published on Nov. 2, 2023), the entire disclosures of which are incorporated by reference herein.

Data centers may provide services (e.g., space, cooling, etc.) to computers for many clients (e.g., tenants). Techniques are provided that allow a tenant or the data center operator their cooling utilization. For example, cooling utilization may be provided as an index or a percentage of the total cooling available in the data center or in a computer rack. The cooling utilization may also be provided as a percentage of the total cooling currently used by the data center. In some embodiments, cooling requirements may be predicted using the power usage of the computer equipment allowing for more efficient and localized supply of cooling. A damper, for example, could be used to control air flow through certain racks of the data center.

Control systems may have access to information to predict failures and/or take corrective action. Health indices can be calculated for each computer, each rack, and/or each customer of the data center. Monitoring of health indices using CPU temperature, rack temperature, air flow, RAM usage, etc. may be indicative of an upcoming fault, predictable using machine learning techniques. Similarly, systems and methods can indicate if preventative maintenance is required. Combination of data by the control system can provide efficiencies that allow the elimination of additional sensors. Aspiration smoke detectors (ASD), which are costly to install but required in a data center due to the high air flow rate, may be placed in the return duct (e.g., false ceiling plenum) and combined with temperature readings from a rack to identify problem areas and slow or stop operations before a computer breakdown a fire.

### Building and Building Management System

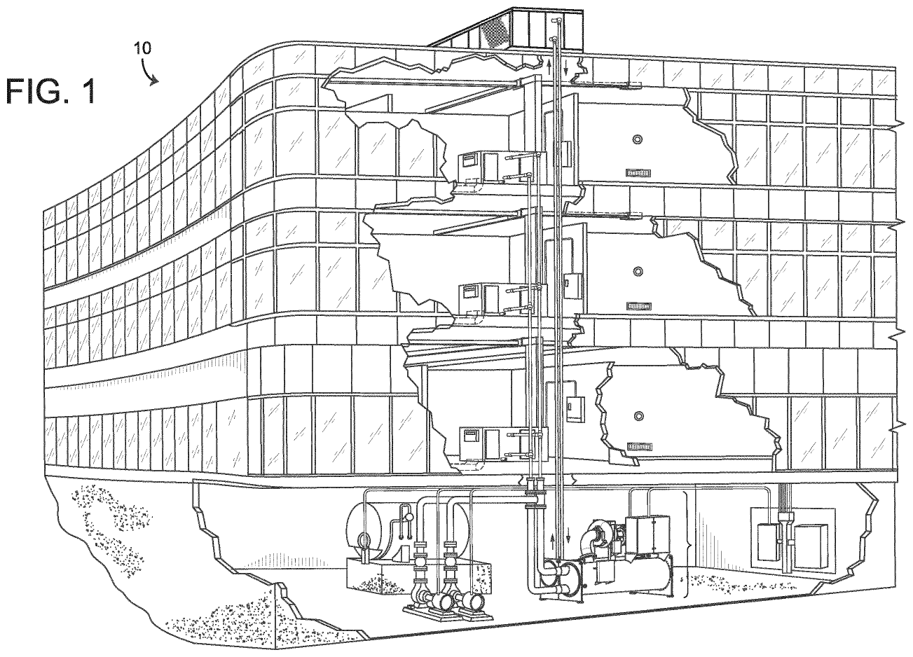

Referring now to FIG. 1, a perspective view of a building 10 is shown, according to an exemplary embodiment. A BMS serves building 10. The BMS for building 10 may include any number or type of devices that serve building 10. For example, each floor may include one or more security devices, video surveillance cameras, fire detectors, smoke detectors, lighting systems, HVAC systems, or other building systems or devices. In modern BMSs, BMS devices can exist on different networks within the building (e.g., one or more wireless networks, one or more wired networks, etc.) and yet serve the same building space or control loop. For example, BMS devices may be connected to different communications networks or field controllers even if the devices serve the same area (e.g., floor, conference room, building zone, tenant area, etc.) or purpose (e.g., security, ventilation, cooling, heating, etc.).

BMS devices may collectively or individually be referred to as building equipment. Building equipment may include any number or type of BMS devices within or around building 10. For example, building equipment may include controllers, chillers, rooftop units, fire and security systems, elevator systems, thermostats, lighting, serviceable equipment (e.g., vending machines), and/or any other type of equipment that can be used to control, automate, or otherwise contribute to an environment, state, or condition of building 10. The terms “BMS devices,” “BMS device” and “building equipment” are used interchangeably throughout this disclosure.

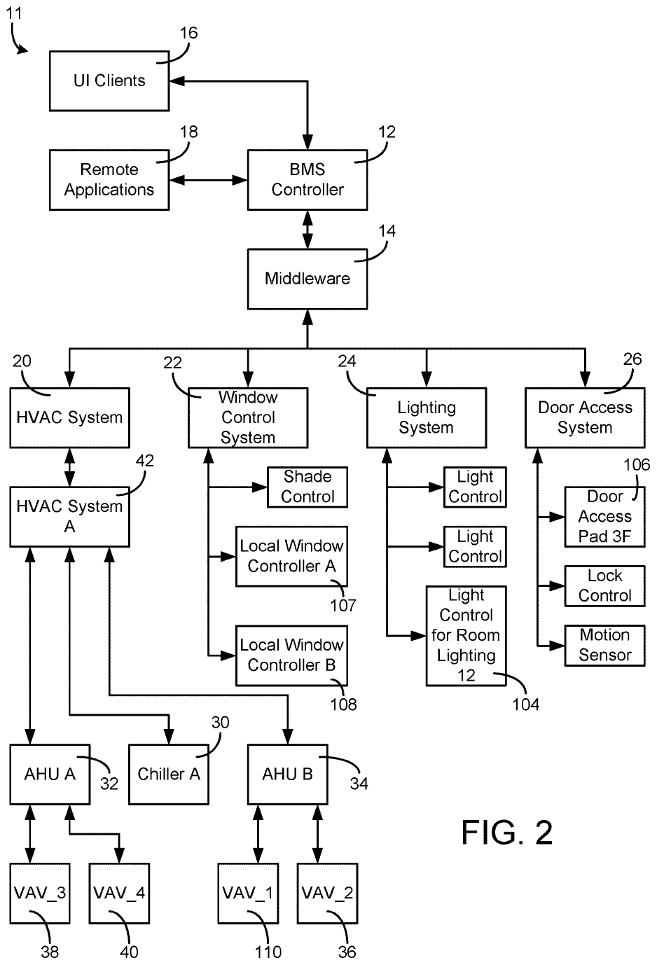

Referring now to FIG. 2, a block diagram of a BMS 11 for building 10 is shown, according to an exemplary embodiment. BMS 11 is shown to include a plurality of BMS subsystems 20-26. Each BMS subsystem 20-26 is connected to a plurality of BMS devices and makes data points for varying connected devices available to upstream BMS controller 12. Additionally, BMS subsystems 20-26 may encompass other lower-level subsystems. For example, an HVAC system may be broken down further as “HVAC system A,” “HVAC system B,” etc. In some buildings, multiple HVAC systems or subsystems may exist in parallel and may not be a part of the same HVAC system 20.

As shown in FIG. 2, BMS 11 may include a HVAC system 20. HVAC system 20 may control HVAC operations building 10. HVAC system 20 is shown to include a lower-level HVAC system 42 (named “HVAC system A”). HVAC system 42 may control HVAC operations for a specific floor or zone of building 10. HVAC system 42 may be connected to air handling units (AHUs) 32, 34 (named “AHU A” and “AHU B,” respectively, in BMS 11). AHU 32 may serve variable air volume (VAV) boxes 38, 40 (named “VAV_3” and “VAV_4” in BMS 11). Likewise, AHU 34 may serve VAV boxes 36 and 110 (named “VAV_2” and “VAV_1”). HVAC system 42 may also include chiller 30 (named “Chiller A” in BMS 11). Chiller 30 may provide chilled fluid to AHU 32 and/or to AHU 34. HVAC system 42 may receive data (i.e., BMS inputs such as temperature sensor readings, damper positions, temperature setpoints, etc.) from AHUs 32, 34. HVAC system 42 may provide such BMS inputs to HVAC system 20 and on to middleware 14 and BMS controller 12. Similarly, other BMS subsystems may receive inputs from other building devices or objects and provide the received inputs to BMS controller 12 (e.g., via middleware 14).

Middleware 14 may include services that allow interoperable communication to, from, or between disparate BMS subsystems 20-26 of BMS 11 (e.g., HVAC systems from different manufacturers, HVAC systems that communicate according to different protocols, security/fire systems, IT resources, door access systems, etc.). Middleware 14 may be, for example, an EnNet server sold by Johnson Controls, Inc. While middleware 14 is shown as separate from BMS controller 12, middleware 14 and BMS controller 12 may integrated in some embodiments. For example, middleware 14 may be a part of BMS controller 12.

Still referring to FIG. 2, window control system 22 may receive shade control information from one or more shade controls, ambient light level information from one or more light sensors, and/or other BMS inputs (e.g., sensor information, setpoint information, current state information, etc.) from downstream devices. Window control system 22 may include window controllers 107, 108 (e.g., named “local window controller A” and “local window controller B,” respectively, in BMS 11). Window controllers 107, 108 control the operation of subsets of window control system 22. For example, window controller 108 may control window blind or shade operations for a given room, floor, or building in the BMS.

Lighting system 24 may receive lighting related information from a plurality of downstream light controls (e.g., from room lighting 104). Door access system 26 may receive lock control, motion, state, or other door related information from a plurality of downstream door controls. Door access system 26 is shown to include door access pad 106 (named “Door Access Pad 3F”), which may grant or deny access to a building space (e.g., a floor, a conference room, an office, etc.) based on whether valid user credentials are scanned or entered (e.g., via a keypad, via a badge-scanning pad, etc.).

BMS subsystems 20-26 may be connected to BMS controller 12 via middleware 14 and may be configured to provide BMS controller 12 with BMS inputs from various BMS subsystems 20-26 and their varying downstream devices. BMS controller 12 may be configured to make differences in building subsystems transparent at the human-machine interface or client interface level (e.g., for connected or hosted user interface (UI) clients 16, remote applications 18, etc.). BMS controller 12 may be configured to describe or model different building devices and building subsystems using common or unified objects (e.g., software objects stored in memory) to help provide the transparency. Software equipment objects may allow developers to write applications capable of monitoring and/or controlling various types of building equipment regardless of equipment-specific variations (e.g., equipment model, equipment manufacturer, equipment version, etc.). Software building objects may allow developers to write applications capable of monitoring and/or controlling building zones on a zone-by-zone level regardless of the building subsystem makeup.

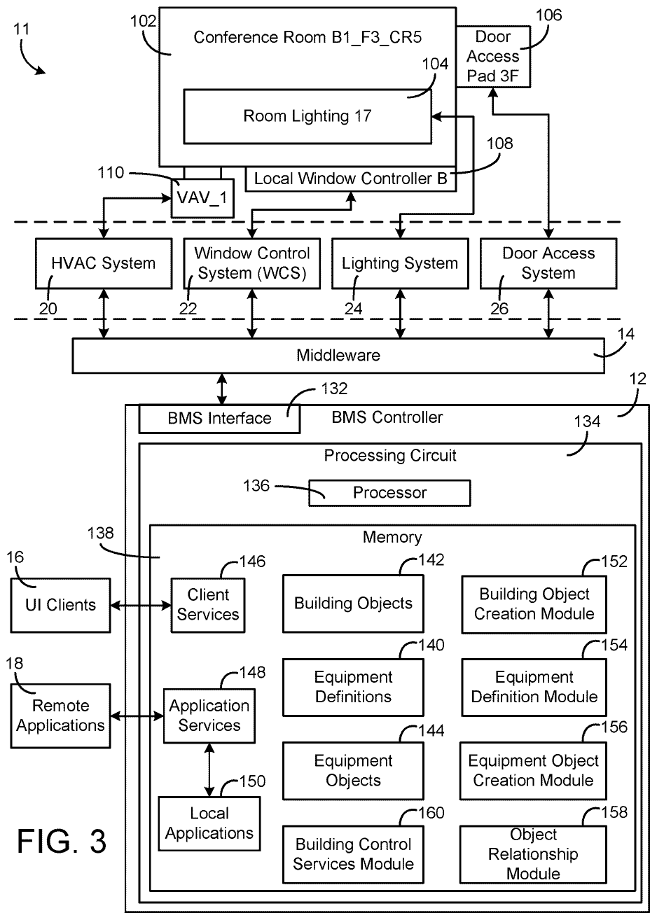

Referring now to FIG. 3, a block diagram illustrating a portion of BMS 11 in greater detail is shown, according to an exemplary embodiment. Particularly, FIG. 3 illustrates a portion of BMS 11 that services a conference room 102 of building 10 (named “B1_F3_CR5”). Conference room 102 may be affected by many different building devices connected to many different BMS subsystems. For example, conference room 102 includes or is otherwise affected by VAV box 110, window controller 108 (e.g., a blind controller), a system of lights 104 (named “Room Lighting 17”), and a door access pad 106.

Each of the building devices shown at the top of FIG. 3 may include local control circuitry configured to provide signals to their supervisory controllers or more generally to the BMS subsystems 20-26. The local control circuitry of the building devices shown at the top of FIG. 3 may also be configured to receive and respond to control signals, commands, setpoints, or other data from their supervisory controllers. For example, the local control circuitry of VAV box 110 may include circuitry that affects an actuator in response to control signals received from a field controller that is a part of HVAC system 20. Window controller 108 may include circuitry that affects windows or blinds in response to control signals received from a field controller that is part of window control system (WCS) 22. Room lighting 104 may include circuitry that affects the lighting in response to control signals received from a field controller that is part of lighting system 24. Access pad 106 may include circuitry that affects door access (e.g., locking or unlocking the door) in response to control signals received from a field controller that is part of door access system 26.

Still referring to FIG. 3, BMS controller 12 is shown to include a BMS interface 132 in communication with middleware 14. In some embodiments, BMS interface 132 is a communications interface. For example, BMS interface 132 may include wired or wireless interfaces (e.g., jacks, antennas, transmitters, receivers, transceivers, wire terminals, etc.) for conducting data communications with various systems, devices, or networks. BMS interface 132 can include an Ethernet card and port for sending and receiving data via an Ethernet-based communications network. In another example, BMS interface 132 includes a Wi-Fi transceiver for communicating via a wireless communications network. BMS interface 132 may be configured to communicate via local area networks or wide area networks (e.g., the Internet, a building WAN, etc.).

In some embodiments, BMS interface 132 and/or middleware 14 includes an application gateway configured to receive input from applications running on client devices. For example, BMS interface 132 and/or middleware 14 may include one or more wireless transceivers (e.g., a Wi-Fi transceiver, a Bluetooth transceiver, a NFC transceiver, a cellular transceiver, etc.) for communicating with client devices. BMS interface 132 may be configured to receive building management inputs from middleware 14 or directly from one or more BMS subsystems 20-26. BMS interface 132 and/or middleware 14 can include any number of software buffers, queues, listeners, filters, translators, or other communications-supporting services.

Still referring to FIG. 3, BMS controller 12 is shown to include a processing circuit 134 including a processor 136 and memory 138. Processor 136 may be a general purpose or specific purpose processor, an application specific integrated circuit (ASIC), one or more field programmable gate arrays (FPGAs), a group of processing components, or other suitable processing components. Processor 136 is configured to execute computer code or instructions stored in memory 138 or received from other computer readable media (e.g., CDROM, network storage, a remote server, etc.).

Memory 138 may include one or more devices (e.g., memory units, memory devices, storage devices, etc.) for storing data and/or computer code for completing and/or facilitating the various processes described in the present disclosure. Memory 138 may include random access memory (RAM), read-only memory (ROM), hard drive storage, temporary storage, non-volatile memory, flash memory, optical memory, or any other suitable memory for storing software objects and/or computer instructions. Memory 138 may include database components, object code components, script components, or any other type of information structure for supporting the various activities and information structures described in the present disclosure. Memory 138 may be communicably connected to processor 136 via processing circuit 134 and may include computer code for executing (e.g., by processor 136) one or more processes described herein. When processor 136 executes instructions stored in memory 138 for completing the various activities described herein, processor 136 generally configures BMS controller 12 (and more particularly processing circuit 134) to complete such activities.

Still referring to FIG. 3, memory 138 is shown to include building objects 142. In some embodiments, BMS controller 12 uses building objects 142 to group otherwise ungrouped or unassociated devices so that the group may be addressed or handled by applications together and in a consistent manner (e.g., a single user interface for controlling all of the BMS devices that affect a particular building zone or room). Building objects can apply to spaces of any granularity. For example, a building object can represent an entire building, a floor of a building, or individual rooms on each floor. In some embodiments, BMS controller 12 creates and/or stores a building object in memory 138 for each zone or room of building 10. Building objects 142 can be accessed by UI clients 16 and remote applications 18 to provide a comprehensive user interface for controlling and/or viewing information for a particular building zone. Building objects 142 may be created by building object creation module 152 and associated with equipment objects by object relationship module 158, described in greater detail below.

Still referring to FIG. 3, memory 138 is shown to include equipment definitions 140. Equipment definitions 140 stores the equipment definitions for various types of building equipment. Each equipment definition may apply to building equipment of a different type. For example, equipment definitions 140 may include different equipment definitions for variable air volume modular assemblies (VMAs), fan coil units, air handling units (AHUs), lighting fixtures, water pumps, and/or other types of building equipment.

Equipment definitions 140 define the types of data points that are generally associated with various types of building equipment. For example, an equipment definition for VMA may specify data point types such as room temperature, damper position, supply air flow, and/or other types data measured or used by the VMA. Equipment definitions 140 allow for the abstraction (e.g., generalization, normalization, broadening, etc.) of equipment data from a specific BMS device so that the equipment data can be applied to a room or space.

Each of equipment definitions 140 may include one or more point definitions. Each point definition may define a data point of a particular type and may include search criteria for automatically discovering and/or identifying data points that satisfy the point definition. An equipment definition can be applied to multiple pieces of building equipment of the same general type (e.g., multiple different VMA controllers). When an equipment definition is applied to a BMS device, the search criteria specified by the point definitions can be used to automatically identify data points provided by the BMS device that satisfy each point definition.

In some embodiments, equipment definitions 140 define data point types as generalized types of data without regard to the model, manufacturer, vendor, or other differences between building equipment of the same general type. The generalized data points defined by equipment definitions 140 allows each equipment definition to be referenced by or applied to multiple different variants of the same type of building equipment.

In some embodiments, equipment definitions 140 facilitate the presentation of data points in a consistent and user-friendly manner. For example, each equipment definition may define one or more data points that are displayed via a user interface. The displayed data points may be a subset of the data points defined by the equipment definition.

In some embodiments, equipment definitions 140 specify a system type (e.g., HVAC, lighting, security, fire, etc.), a system sub-type (e.g., terminal units, air handlers, central plants), and/or data category (e.g., critical, diagnostic, operational) associated with the building equipment defined by each equipment definition. Specifying such attributes of building equipment at the equipment definition level allows the attributes to be applied to the building equipment along with the equipment definition when the building equipment is initially defined. Building equipment can be filtered by various attributes provided in the equipment definition to facilitate the reporting and management of equipment data from multiple building systems.

Equipment definitions 140 can be automatically created by abstracting the data points provided by archetypal controllers (e.g., typical or representative controllers) for various types of building equipment. In some embodiments, equipment definitions 140 are created by equipment definition module 154, described in greater detail below.

Still referring to FIG. 3, memory 138 is shown to include equipment objects 144. Equipment objects 144 may be software objects that define a mapping between a data point type (e.g., supply air temperature, room temperature, damper position) and an actual data point (e.g., a measured or calculated value for the corresponding data point type) for various pieces of building equipment. Equipment objects 144 may facilitate the presentation of equipment-specific data points in an intuitive and user-friendly manner by associating each data point with an attribute identifying the corresponding data point type. The mapping provided by equipment objects 144 may be used to associate a particular data value measured or calculated by BMS 11 with an attribute that can be displayed via a user interface.

Equipment objects 144 can be created (e.g., by equipment object creation module 156) by referencing equipment definitions 140. For example, an equipment object can be created by applying an equipment definition to the data points provided by a BMS device. The search criteria included in an equipment definition can be used to identify data points of the building equipment that satisfy the point definitions. A data point that satisfies a point definition can be mapped to an attribute of the equipment object corresponding to the point definition.

Each equipment object may include one or more attributes defined by the point definitions of the equipment definition used to create the equipment object. For example, an equipment definition which defines the attributes “Occupied Command,” “Room Temperature,” and “Damper Position” may result in an equipment object being created with the same attributes. The search criteria provided by the equipment definition are used to identify and map data points associated with a particular BMS device to the attributes of the equipment object. The creation of equipment objects is described in greater detail below with reference to equipment object creation module 156.

Equipment objects 144 may be related with each other and/or with building objects 142. Causal relationships can be established between equipment objects to link equipment objects to each other. For example, a causal relationship can be established between a VMA and an AHU which provides airflow to the VMA. Causal relationships can also be established between equipment objects 144 and building objects 142. For example, equipment objects 144 can be associated with building objects 142 representing particular rooms or zones to indicate that the equipment object serves that room or zone. Relationships between objects are described in greater detail below with reference to object relationship module 158.

Still referring to FIG. 3, memory 138 is shown to include client services 146 and application services 148. Client services 146 may be configured to facilitate interaction and/or communication between BMS controller 12 and various internal or external clients or applications. For example, client services 146 may include web services or application programming interfaces available for communication by UI clients 16 and remote applications 18 (e.g., applications running on a mobile device, energy monitoring applications, applications allowing a user to monitor the performance of the BMS, automated fault detection and diagnostics systems, etc.). Application services 148 may facilitate direct or indirect communications between remote applications 18, local applications 150, and BMS controller 12. For example, application services 148 may allow BMS controller 12 to communicate (e.g., over a communications network) with remote applications 18 running on mobile devices and/or with other BMS controllers.

In some embodiments, application services 148 facilitate an applications gateway for conducting electronic data communications with UI clients 16 and/or remote applications 18. For example, application services 148 may be configured to receive communications from mobile devices and/or BMS devices. Client services 146 may provide client devices with a graphical user interface that consumes data points and/or display data defined by equipment definitions 140 and mapped by equipment objects 144.

Still referring to FIG. 3, memory 138 is shown to include a building object creation module 152. Building object creation module 152 may be configured to create the building objects stored in building objects 142. Building object creation module 152 may create a software building object for various spaces within building 10. Building object creation module 152 can create a building object for a space of any size or granularity. For example, building object creation module 152 can create a building object representing an entire building, a floor of a building, or individual rooms on each floor. In some embodiments, building object creation module 152 creates and/or stores a building object in memory 138 for each zone or room of building 10.

The building objects created by building object creation module 152 can be accessed by UI clients 16 and remote applications 18 to provide a comprehensive user interface for controlling and/or viewing information for a particular building zone. Building objects 142 can group otherwise ungrouped or unassociated devices so that the group may be addressed or handled by applications together and in a consistent manner (e.g., a single user interface for controlling all of the BMS devices that affect a particular building zone or room). In some embodiments, building object creation module 152 uses the systems and methods described in U.S. patent application Ser. No. 12/887,390, filed Sep. 21, 2010, for creating software defined building objects.

In some embodiments, building object creation module 152 provides a user interface for guiding a user through a process of creating building objects. For example, building object creation module 152 may provide a user interface to client devices (e.g., via client services 146) that allows a new space to be defined. In some embodiments, building object creation module 152 defines spaces hierarchically. For example, the user interface for creating building objects may prompt a user to create a space for a building, for floors within the building, and/or for rooms or zones within each floor.

In some embodiments, building object creation module 152 creates building objects automatically or semi-automatically. For example, building object creation module 152 may automatically define and create building objects using data imported from another data source (e.g., user view folders, a table, a spreadsheet, etc.). In some embodiments, building object creation module 152 references an existing hierarchy for BMS 11 to define the spaces within building 10. For example, BMS 11 may provide a listing of controllers for building 10 (e.g., as part of a network of data points) that have the physical location (e.g., room name) of the controller in the name of the controller itself. Building object creation module 152 may extract room names from the names of BMS controllers defined in the network of data points and create building objects for each extracted room. Building objects may be stored in building objects 142.

Still referring to FIG. 3, memory 138 is shown to include an equipment definition module 154. Equipment definition module 154 may be configured to create equipment definitions for various types of building equipment and to store the equipment definitions in equipment definitions 140. In some embodiments, equipment definition module 154 creates equipment definitions by abstracting the data points provided by archetypal controllers (e.g., typical or representative controllers) for various types of building equipment. For example, equipment definition module 154 may receive a user selection of an archetypal controller via a user interface. The archetypal controller may be specified as a user input or selected automatically by equipment definition module 154. In some embodiments, equipment definition module 154 selects an archetypal controller for building equipment associated with a terminal unit such as a VMA.

Equipment definition module 154 may identify one or more data points associated with the archetypal controller. Identifying one or more data points associated with the archetypal controller may include accessing a network of data points provided by BMS 11. The network of data points may be a hierarchical representation of data points that are measured, calculated, or otherwise obtained by various BMS devices. BMS devices may be represented in the network of data points as nodes of the hierarchical representation with associated data points depending from each BMS device. Equipment definition module 154 may find the node corresponding to the archetypal controller in the network of data points and identify one or more data points which depend from the archetypal controller node.

Equipment definition module 154 may generate a point definition for each identified data point of the archetypal controller. Each point definition may include an abstraction of the corresponding data point that is applicable to multiple different controllers for the same type of building equipment. For example, an archetypal controller for a particular VMA (i.e., “VMA-20”) may be associated an equipment-specific data point such as “VMA-20.DPR-POS” (i.e., the damper position of VMA-20) and/or “VMA-20.SUP-FLOW” (i.e., the supply air flow rate through VMA-20). Equipment definition module 154 abstract the equipment-specific data points to generate abstracted data point types that are generally applicable to other equipment of the same type. For example, equipment definition module 154 may abstract the equipment-specific data point “VMA-20.DPR-POS” to generate the abstracted data point type “DPR-POS” and may abstract the equipment-specific data point “VMA-20.SUP-FLOW” to generate the abstracted data point type “SUP-FLOW.” Advantageously, the abstracted data point types generated by equipment definition module 154 can be applied to multiple different variants of the same type of building equipment (e.g., VMAs from different manufacturers, VMAs having different models or output data formats, etc.).

In some embodiments, equipment definition module 154 generates a user-friendly label for each point definition. The user-friendly label may be a plain text description of the variable defined by the point definition. For example, equipment definition module 154 may generate the label “Supply Air Flow” for the point definition corresponding to the abstracted data point type “SUP-FLOW” to indicate that the data point represents a supply air flow rate through the VMA. The labels generated by equipment definition module 154 may be displayed in conjunction with data values from BMS devices as part of a user-friendly interface.

In some embodiments, equipment definition module 154 generates search criteria for each point definition. The search criteria may include one or more parameters for identifying another data point (e.g., a data point associated with another controller of BMS 11 for the same type of building equipment) that represents the same variable as the point definition. Search criteria may include, for example, an instance number of the data point, a network address of the data point, and/or a network point type of the data point.

In some embodiments, search criteria include a text string abstracted from a data point associated with the archetypal controller. For example, equipment definition module 154 may generate the abstracted text string “SUP-FLOW” from the equipment-specific data point “VMA-20.SUP-FLOW.” Advantageously, the abstracted text string matches other equipment-specific data points corresponding to the supply air flow rates of other BMS devices (e.g., “VMA-18.SUP-FLOW,” “SUP-FLOW.VMA-01,” etc.). Equipment definition module 154 may store a name, label, and/or search criteria for each point definition in memory 138.

Equipment definition module 154 may use the generated point definitions to create an equipment definition for a particular type of building equipment (e.g., the same type of building equipment associated with the archetypal controller). The equipment definition may include one or more of the generated point definitions. Each point definition defines a potential attribute of BMS devices of the particular type and provides search criteria for identifying the attribute among other data points provided by such BMS devices.

In some embodiments, the equipment definition created by equipment definition module 154 includes an indication of display data for BMS devices that reference the equipment definition. Display data may define one or more data points of the BMS device that will be displayed via a user interface. In some embodiments, display data are user defined. For example, equipment definition module 154 may prompt a user to select one or more of the point definitions included in the equipment definition to be represented in the display data. Display data may include the user-friendly label (e.g., “Damper Position”) and/or short name (e.g., “DPR-POS”) associated with the selected point definitions.

In some embodiments, equipment definition module 154 provides a visualization of the equipment definition via a graphical user interface. The visualization of the equipment definition may include a point definition portion which displays the generated point definitions, a user input portion configured to receive a user selection of one or more of the point definitions displayed in the point definition portion, and/or a display data portion which includes an indication of an abstracted data point corresponding to each of the point definitions selected via the user input portion. The visualization of the equipment definition can be used to add, remove, or change point definitions and/or display data associated with the equipment definitions.

Equipment definition module 154 may generate an equipment definition for each different type of building equipment in BMS 11 (e.g., VMAs, chillers, AHUs, etc.). Equipment definition module 154 may store the equipment definitions in a data storage device (e.g., memory 138, equipment definitions 140, an external or remote data storage device, etc.).

Still referring to FIG. 3, memory 138 is shown to include an equipment object creation module 156. Equipment object creation module 156 may be configured to create equipment objects for various BMS devices. In some embodiments, equipment object creation module 156 creates an equipment object by applying an equipment definition to the data points provided by a BMS device. For example, equipment object creation module 156 may receive an equipment definition created by equipment definition module 154. Receiving an equipment definition may include loading or retrieving the equipment definition from a data storage device.

In some embodiments, equipment object creation module 156 determines which of a plurality of equipment definitions to retrieve based on the type of BMS device used to create the equipment object. For example, if the BMS device is a VMA, equipment object creation module 156 may retrieve the equipment definition for VMAs; whereas if the BMS device is a chiller, equipment object creation module 156 may retrieve the equipment definition for chillers. The type of BMS device to which an equipment definition applies may be stored as an attribute of the equipment definition. Equipment object creation module 156 may identify the type of BMS device being used to create the equipment object and retrieve the corresponding equipment definition from the data storage device.

In other embodiments, equipment object creation module 156 receives an equipment definition prior to selecting a BMS device. Equipment object creation module 156 may identify a BMS device of BMS 11 to which the equipment definition applies. For example, equipment object creation module 156 may identify a BMS device that is of the same type of building equipment as the archetypal BMS device used to generate the equipment definition. In various embodiments, the BMS device used to generate the equipment object may be selected automatically (e.g., by equipment object creation module 156), manually (e.g., by a user) or semi-automatically (e.g., by a user in response to an automated prompt from equipment object creation module 156).

In some embodiments, equipment object creation module 156 creates an equipment discovery table based on the equipment definition. For example, equipment object creation module 156 may create an equipment discovery table having attributes (e.g., columns) corresponding to the variables defined by the equipment definition (e.g., a damper position attribute, a supply air flow rate attribute, etc.). Each column of the equipment discovery table may correspond to a point definition of the equipment definition. The equipment discovery table may have columns that are categorically defined (e.g., representing defined variables) but not yet mapped to any particular data points.

Equipment object creation module 156 may use the equipment definition to automatically identify one or more data points of the selected BMS device to map to the columns of the equipment discovery table. Equipment object creation module 156 may search for data points of the BMS device that satisfy one or more of the point definitions included in the equipment definition. In some embodiments, equipment object creation module 156 extracts a search criterion from each point definition of the equipment definition. Equipment object creation module 156 may access a data point network of the building automation system to identify one or more data points associated with the selected BMS device. Equipment object creation module 156 may use the extracted search criterion to determine which of the identified data points satisfy one or more of the point definitions.

In some embodiments, equipment object creation module 156 automatically maps (e.g., links, associates, relates, etc.) the identified data points of selected BMS device to the equipment discovery table. A data point of the selected BMS device may be mapped to a column of the equipment discovery table in response to a determination by equipment object creation module 156 that the data point satisfies the point definition (e.g., the search criteria) used to generate the column. For example, if a data point of the selected BMS device has the name “VMA-18.SUP-FLOW” and a search criterion is the text string “SUP-FLOW,” equipment object creation module 156 may determine that the search criterion is met. Accordingly, equipment object creation module 156 may map the data point of the selected BMS device to the corresponding column of the equipment discovery table.

Advantageously, equipment object creation module 156 may create multiple equipment objects and map data points to attributes of the created equipment objects in an automated fashion (e.g., without human intervention, with minimal human intervention, etc.). The search criteria provided by the equipment definition facilitates the automatic discovery and identification of data points for a plurality of equipment object attributes. Equipment object creation module 156 may label each attribute of the created equipment objects with a device-independent label derived from the equipment definition used to create the equipment object. The equipment objects created by equipment object creation module 156 can be viewed (e.g., via a user interface) and/or interpreted by data consumers in a consistent and intuitive manner regardless of device-specific differences between BMS devices of the same general type. The equipment objects created by equipment object creation module 156 may be stored in equipment objects 144.

Still referring to FIG. 3, memory 138 is shown to include an object relationship module 158. Object relationship module 158 may be configured to establish relationships between equipment objects 144. In some embodiments, object relationship module 158 establishes causal relationships between equipment objects 144 based on the ability of one BMS device to affect another BMS device. For example, object relationship module 158 may establish a causal relationship between a terminal unit (e.g., a VMA) and an upstream unit (e.g., an AHU, a chiller, etc.) which affects an input provided to the terminal unit (e.g., air flow rate, air temperature, etc.).

Object relationship module 158 may establish relationships between equipment objects 144 and building objects 142 (e.g., spaces). For example, object relationship module 158 may associate equipment objects 144 with building objects 142 representing particular rooms or zones to indicate that the equipment object serves that room or zone. In some embodiments, object relationship module 158 provides a user interface through which a user can define relationships between equipment objects 144 and building objects 142. For example, a user can assign relationships in a “drag and drop” fashion by dragging and dropping a building object and/or an equipment object into a “serving” cell of an equipment object provided via the user interface to indicate that the BMS device represented by the equipment object serves a particular space or BMS device.

Still referring to FIG. 3, memory 138 is shown to include a building control services module 160. Building control services module 160 may be configured to automatically control BMS 11 and the various subsystems thereof. Building control services module 160 may utilize closed loop control, feedback control, PI control, model predictive control, or any other type of automated building control methodology to control the environment (e.g., a variable state or condition) within building 10.

Building control services module 160 may receive inputs from sensory devices (e.g., temperature sensors, pressure sensors, flow rate sensors, humidity sensors, electric current sensors, cameras, radio frequency sensors, microphones, etc.), user input devices (e.g., computer terminals, client devices, user devices, etc.) or other data input devices via BMS interface 132. Building control services module 160 may apply the various inputs to a building energy use model and/or a control algorithm to determine an output for one or more building control devices (e.g., dampers, air handling units, chillers, boilers, fans, pumps, etc.) in order to affect a variable state or condition within building 10 (e.g., zone temperature, humidity, air flow rate, etc.).

In some embodiments, building control services module 160 is configured to control the environment of building 10 on a zone-individualized level. For example, building control services module 160 may control the environment of two or more different building zones using different setpoints, different constraints, different control methodology, and/or different control parameters. Building control services module 160 may operate BMS 11 to maintain building conditions (e.g., temperature, humidity, air quality, etc.) within a setpoint range, to optimize energy performance (e.g., to minimize energy consumption, to minimize energy cost, etc.), and/or to satisfy any constraint or combination of constraints as may be desirable for various implementations.

In some embodiments, building control services module 160 uses the location of various BMS devices to translate an input received from a building system into an output or control signal for the building system. Building control services module 160 may receive location information for BMS devices and automatically set or recommend control parameters for the BMS devices based on the locations of the BMS devices. For example, building control services module 160 may automatically set a flow rate setpoint for a VAV box based on the size of the building zone in which the VAV box is located.

Building control services module 160 may determine which of a plurality of sensors to use in conjunction with a feedback control loop based on the locations of the sensors within building 10. For example, building control services module 160 may use a signal from a temperature sensor located in a building zone as a feedback signal for controlling the temperature of the building zone in which the temperature sensor is located.

In some embodiments, building control services module 160 automatically generates control algorithms for a controller or a building zone based on the location of the zone in the building 10. For example, building control services module 160 may be configured to predict a change in demand resulting from sunlight entering through windows based on the orientation of the building and the locations of the building zones (e.g., east-facing, west-facing, perimeter zones, interior zones, etc.).

Building control services module 160 may use zone location information and interactions between adjacent building zones (rather than considering each zone as an isolated system) to more efficiently control the temperature and/or airflow within building 10. For control loops that are conducted at a larger scale (i.e., floor level) building control services module 160 may use the location of each building zone and/or BMS device to coordinate control functionality between building zones. For example, building control services module 160 may consider heat exchange and/or air exchange between adjacent building zones as a factor in determining an output control signal for the building zones.

In some embodiments, building control services module 160 is configured to optimize the energy efficiency of building 10 using the locations of various BMS devices and the control parameters associated therewith. Building control services module 160 may be configured to achieve control setpoints using building equipment with a relatively lower energy cost (e.g., by causing airflow between connected building zones) in order to reduce the loading on building equipment with a relatively higher energy cost (e.g., chillers and roof top units). For example, building control services module 160 may be configured to move warmer air from higher elevation zones to lower elevation zones by establishing pressure gradients between connected building zones.

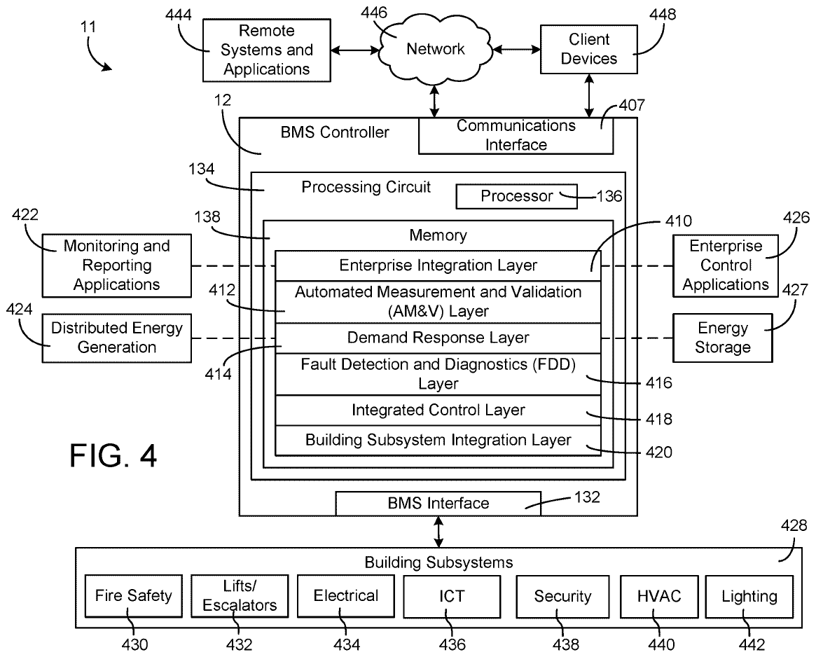

Referring now to FIG. 4, another block diagram illustrating a portion of BMS 11 in greater detail is shown, according to some embodiments. BMS 11 can be implemented in building 10 to automatically monitor and control various building functions. BMS 11 is shown to include BMS controller 12 and a plurality of building subsystems 428. Building subsystems 428 are shown to include a building electrical subsystem 434, an information communication technology (ICT) subsystem 436, a security subsystem 438, a HVAC subsystem 440, a lighting subsystem 442, a lift/escalators subsystem 432, and a fire safety subsystem 430. In various embodiments, building subsystems 428 can include fewer, additional, or alternative subsystems. For example, building subsystems 428 may also or alternatively include a refrigeration subsystem, an advertising or signage subsystem, a cooking subsystem, a vending subsystem, a printer or copy service subsystem, or any other type of building subsystem that uses controllable equipment and/or sensors to monitor or control building 10.

Each of building subsystems 428 can include any number of devices, controllers, and connections for completing its individual functions and control activities. HVAC subsystem 440 can include many of the same components as HVAC system 20, as described with reference to FIGS. 2-3. For example, HVAC subsystem 440 can include a chiller, a boiler, any number of air handling units, economizers, field controllers, supervisory controllers, actuators, temperature sensors, and other devices for controlling the temperature, humidity, airflow, or other variable conditions within building 10. Lighting subsystem 442 can include any number of light fixtures, ballasts, lighting sensors, dimmers, or other devices configured to controllably adjust the amount of light provided to a building space. Security subsystem 438 can include occupancy sensors, video surveillance cameras, digital video recorders, video processing servers, intrusion detection devices, access control devices and servers, or other security-related devices.

Still referring to FIG. 4, BMS controller 12 is shown to include a communications interface 407 and a BMS interface 132. Interface 407 may facilitate communications between BMS controller 12 and external applications (e.g., monitoring and reporting applications 422, enterprise control applications 426, remote systems and applications 444, applications residing on client devices 448, etc.) for allowing user control, monitoring, and adjustment to BMS controller 12 and/or subsystems 428. Interface 407 may also facilitate communications between BMS controller 12 and client devices 448. BMS interface 132 may facilitate communications between BMS controller 12 and building subsystems 428 (e.g., HVAC, lighting security, lifts, power distribution, business, etc.).

Interfaces 407, 132 can be or include wired or wireless communications interfaces (e.g., jacks, antennas, transmitters, receivers, transceivers, wire terminals, etc.) for conducting data communications with building subsystems 428 or other external systems or devices. In various embodiments, communications via interfaces 407, 132 can be direct (e.g., local wired or wireless communications) or via a communications network 446 (e.g., a WAN, the Internet, a cellular network, etc.). For example, interfaces 407, 132 can include an Ethernet card and port for sending and receiving data via an Ethernet-based communications link or network. In another example, interfaces 407, 132 can include a Wi-Fi transceiver for communicating via a wireless communications network. In another example, one or both of interfaces 407, 132 can include cellular or mobile phone communications transceivers. In one embodiment, communications interface 407 is a power line communications interface and BMS interface 132 is an Ethernet interface. In other embodiments, both communications interface 407 and BMS interface 132 are Ethernet interfaces or are the same Ethernet interface.

Still referring to FIG. 4, BMS controller 12 is shown to include a processing circuit 134 including a processor 136 and memory 138. Processing circuit 134 can be communicably connected to BMS interface 132 and/or communications interface 407 such that processing circuit 134 and the various components thereof can send and receive data via interfaces 407, 132. Processor 136 can be implemented as a general purpose processor, an application specific integrated circuit (ASIC), one or more field programmable gate arrays (FPGAs), a group of processing components, or other suitable electronic processing components.

Memory 138 (e.g., memory, memory unit, storage device, etc.) can include one or more devices (e.g., RAM, ROM, Flash memory, hard disk storage, etc.) for storing data and/or computer code for completing or facilitating the various processes, layers and modules described in the present application. Memory 138 can be or include volatile memory or non-volatile memory. Memory 138 can include database components, object code components, script components, or any other type of information structure for supporting the various activities and information structures described in the present application. According to some embodiments, memory 138 is communicably connected to processor 136 via processing circuit 134 and includes computer code for executing (e.g., by processing circuit 134 and/or processor 136) one or more processes described herein.

In some embodiments, BMS controller 12 is implemented within a single computer (e.g., one server, one housing, etc.). In various other embodiments BMS controller 12 can be distributed across multiple servers or computers (e.g., that can exist in distributed locations). Further, while FIG. 4 shows applications 422 and 426 as existing outside of BMS controller 12, in some embodiments, applications 422 and 426 can be hosted within BMS controller 12 (e.g., within memory 138).

Still referring to FIG. 4, memory 138 is shown to include an enterprise integration layer 410, an automated measurement and validation (AM&V) layer 412, a demand response (DR) layer 414, a fault detection and diagnostics (FDD) layer 416, an integrated control layer 418, and a building subsystem integration later 420. Layers 410-420 can be configured to receive inputs from building subsystems 428 and other data sources, determine optimal control actions for building subsystems 428 based on the inputs, generate control signals based on the optimal control actions, and provide the generated control signals to building subsystems 428. The following paragraphs describe some of the general functions performed by each of layers 410-420 in BMS 11.

Enterprise integration layer 410 can be configured to serve clients or local applications with information and services to support a variety of enterprise-level applications. For example, enterprise control applications 426 can be configured to provide subsystem-spanning control to a graphical user interface (GUI) or to any number of enterprise-level business applications (e.g., accounting systems, user identification systems, etc.). Enterprise control applications 426 may also or alternatively be configured to provide configuration GUIs for configuring BMS controller 12. In yet other embodiments, enterprise control applications 426 can work with layers 410-420 to optimize building performance (e.g., efficiency, energy use, comfort, or safety) based on inputs received at interface 407 and/or BMS interface 132.

Building subsystem integration layer 420 can be configured to manage communications between BMS controller 12 and building subsystems 428. For example, building subsystem integration layer 420 may receive sensor data and input signals from building subsystems 428 and provide output data and control signals to building subsystems 428. Building subsystem integration layer 420 may also be configured to manage communications between building subsystems 428. Building subsystem integration layer 420 translate communications (e.g., sensor data, input signals, output signals, etc.) across a plurality of multi-vendor/multi-protocol systems.

Demand response layer 414 can be configured to optimize resource usage (e.g., electricity use, natural gas use, water use, etc.) and/or the monetary cost of such resource usage in response to satisfy the demand of building 10. The optimization can be based on time-of-use prices, curtailment signals, energy availability, or other data received from utility providers, distributed energy generation systems 424, from energy storage 427, or from other sources. Demand response layer 414 may receive inputs from other layers of BMS controller 12 (e.g., building subsystem integration layer 420, integrated control layer 418, etc.). The inputs received from other layers can include environmental or sensor inputs such as temperature, carbon dioxide levels, relative humidity levels, air quality sensor outputs, occupancy sensor outputs, room schedules, and the like. The inputs may also include inputs such as electrical use (e.g., expressed in kWh), thermal load measurements, pricing information, projected pricing, smoothed pricing, curtailment signals from utilities, and the like.

According to some embodiments, demand response layer 414 includes control logic for responding to the data and signals it receives. These responses can include communicating with the control algorithms in integrated control layer 418, changing control strategies, changing setpoints, or activating/deactivating building equipment or subsystems in a controlled manner. Demand response layer 414 may also include control logic configured to determine when to utilize stored energy. For example, demand response layer 414 may determine to begin using energy from energy storage 427 just prior to the beginning of a peak use hour.

In some embodiments, demand response layer 414 includes a control module configured to actively initiate control actions (e.g., automatically changing setpoints) which minimize energy costs based on one or more inputs representative of or based on demand (e.g., price, a curtailment signal, a demand level, etc.). In some embodiments, demand response layer 414 uses equipment models to determine an optimal set of control actions. The equipment models can include, for example, thermodynamic models describing the inputs, outputs, and/or functions performed by various sets of building equipment. Equipment models may represent collections of building equipment (e.g., subplants, chiller arrays, etc.) or individual devices (e.g., individual chillers, heaters, pumps, etc.).

Demand response layer 414 may further include or draw upon one or more demand response policy definitions (e.g., databases, XML files, etc.). The policy definitions can be edited or adjusted by a user (e.g., via a graphical user interface) so that the control actions initiated in response to demand inputs can be tailored for the user's application, desired comfort level, particular building equipment, or based on other concerns. For example, the demand response policy definitions can specify which equipment can be turned on or off in response to particular demand inputs, how long a system or piece of equipment should be turned off, what setpoints can be changed, what the allowable set point adjustment range is, how long to hold a high demand setpoint before returning to a normally scheduled setpoint, how close to approach capacity limits, which equipment modes to utilize, the energy transfer rates (e.g., the maximum rate, an alarm rate, other rate boundary information, etc.) into and out of energy storage devices (e.g., thermal storage tanks, battery banks, etc.), and when to dispatch on-site generation of energy (e.g., via fuel cells, a motor generator set, etc.).

Integrated control layer 418 can be configured to use the data input or output of building subsystem integration layer 420 and/or demand response later 414 to make control decisions. Due to the subsystem integration provided by building subsystem integration layer 420, integrated control layer 418 can integrate control activities of the subsystems 428 such that the subsystems 428 behave as a single integrated supersystem. In some embodiments, integrated control layer 418 includes control logic that uses inputs and outputs from a plurality of building subsystems to provide greater comfort and energy savings relative to the comfort and energy savings that separate subsystems could provide alone. For example, integrated control layer 418 can be configured to use an input from a first subsystem to make an energy-saving control decision for a second subsystem. Results of these decisions can be communicated back to building subsystem integration layer 420.

Integrated control layer 418 is shown to be logically below demand response layer 414. Integrated control layer 418 can be configured to enhance the effectiveness of demand response layer 414 by enabling building subsystems 428 and their respective control loops to be controlled in coordination with demand response layer 414. This configuration may advantageously reduce disruptive demand response behavior relative to conventional systems. For example, integrated control layer 418 can be configured to assure that a demand response-driven upward adjustment to the setpoint for chilled water temperature (or another component that directly or indirectly affects temperature) does not result in an increase in fan energy (or other energy used to cool a space) that would result in greater total building energy use than was saved at the chiller.

Integrated control layer 418 can be configured to provide feedback to demand response layer 414 so that demand response layer 414 checks that constraints (e.g., temperature, lighting levels, etc.) are properly maintained even while demanded load shedding is in progress. The constraints may also include setpoint or sensed boundaries relating to safety, equipment operating limits and performance, comfort, fire codes, electrical codes, energy codes, and the like. Integrated control layer 418 is also logically below fault detection and diagnostics layer 416 and automated measurement and validation layer 412. Integrated control layer 418 can be configured to provide calculated inputs (e.g., aggregations) to these higher levels based on outputs from more than one building subsystem.

Automated measurement and validation (AM&V) layer 412 can be configured to verify that control strategies commanded by integrated control layer 418 or demand response layer 414 are working properly (e.g., using data aggregated by AM&V layer 412, integrated control layer 418, building subsystem integration layer 420, FDD layer 416, or otherwise). The calculations made by AM&V layer 412 can be based on building system energy models and/or equipment models for individual BMS devices or subsystems. For example, AM&V layer 412 may compare a model-predicted output with an actual output from building subsystems 428 to determine an accuracy of the model.

Fault detection and diagnostics (FDD) layer 416 can be configured to provide on-going fault detection for building subsystems 428, building subsystem devices (i.e., building equipment), and control algorithms used by demand response layer 414 and integrated control layer 418. FDD layer 416 may receive data inputs from integrated control layer 418, directly from one or more building subsystems or devices, or from another data source. FDD layer 416 may automatically diagnose and respond to detected faults. The responses to detected or diagnosed faults can include providing an alert message to a user, a maintenance scheduling system, or a control algorithm configured to attempt to repair the fault or to work-around the fault.

FDD layer 416 can be configured to output a specific identification of the faulty component or cause of the fault (e.g., loose damper linkage) using detailed subsystem inputs available at building subsystem integration layer 420. In other exemplary embodiments, FDD layer 416 is configured to provide “fault” events to integrated control layer 418 which executes control strategies and policies in response to the received fault events. According to some embodiments, FDD layer 416 (or a policy executed by an integrated control engine or business rules engine) may shut-down systems or direct control activities around faulty devices or systems to reduce energy waste, extend equipment life, or assure proper control response.

FDD layer 416 can be configured to store or access a variety of different system data stores (or data points for live data). FDD layer 416 may use some content of the data stores to identify faults at the equipment level (e.g., specific chiller, specific AHU, specific terminal unit, etc.) and other content to identify faults at component or subsystem levels. For example, building subsystems 428 may generate temporal (i.e., time-series) data indicating the performance of BMS 11 and the various components thereof. The data generated by building subsystems 428 can include measured or calculated values that exhibit statistical characteristics and provide information about how the corresponding system or process (e.g., a temperature control process, a flow control process, etc.) is performing in terms of error from its setpoint. These processes can be examined by FDD layer 416 to expose when the system begins to degrade in performance and alert a user to repair the fault before it becomes more severe.

### HVAC Control in Data Centers

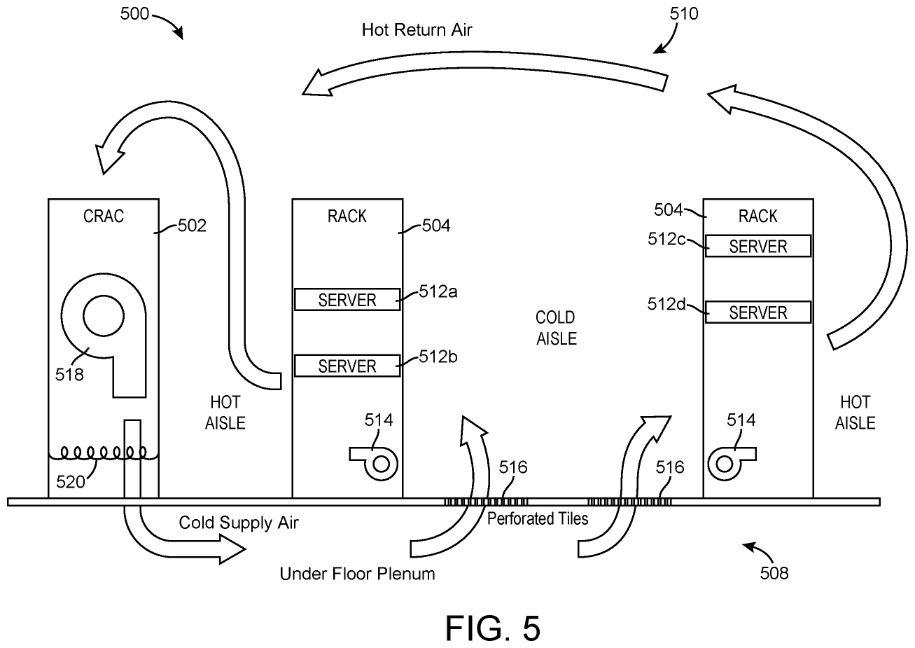

FIG. 5 shows a computer room air conditioner (CRAC) 502 cooling the racks 504 of a data center environment 500. In some embodiments, cooling from the CRAC 502 is provided through an under-floor plenum 508 and perforated tiles 516 to the cold aisle of the racks 504. Heat is exchanged from the CPUs of the servers 512a-d and the cool air provided by the CRAC 502. A hot air return 510 provides a volume where air that has been heated by the CPUs can be drawn back to the CRAC 502 for cooling. The hot air return 510 may be isolated from the cold air through the use of a false ceiling, or the hot air return 510 may rely on the air being drawn through the racks by rack fans 514 and rising due to the natural buoyancy of hotter air. The under-floor plenum 508 and/or hot air return 510 are used to transport air between the CRAC 502 and the racks 504. In some embodiments, ductwork may be used in addition to or in place of the under-floor plenum 508 and/or hot air return 510 to transport the air between the CRAC 502 and the racks 504.

As used herein, the terms “rack” or “computer rack” is intended to be interpreted as any enclosure for multiple computing devices. Such terms should be understood to encompass computer cabinets, server racks, information technology (IT) racks, data racks, network racks, server enclosures, data center racks, colocation racks, technology racks, blade enclosures, hardware racks, and other similar terminology. Similarly, the term “computer” is intended to be interpreted in its broad sense and encompass any computing device including servers, blades, switches, routers, storage devices, processors, central processing units (CPUs), graphics processing units (GPUs), and similar hardware.

The CRAC 502 may include a supply fan 518 to draw hot air from the hot air return 510 through the CRAC 502 and across a cooling coil 520. The supply fan 518 may be controlled to maintain a constant temperature (e.g., a return air temperature, an average computer temperature, etc.) or may be controlled to maintain proper air flow (e.g., prevent backflow of hot air into the racks) through the data center environment 500 by volume matching with rack fans 514 or CPU fans that pull air from the cold aisle.

The cooling coil 520 may be any device that can reduce the temperature of the air stream flowing through the CRAC 502. The CRAC 502 may be a direct expansion device, and the cooling coil 520 may be the evaporator-side heat exchanger of the refrigerant cycle. The CRAC 502 may be configured as a CRAH, and the cooling coil 520 may carry chilled water from a chiller (e.g., of a central plant system). The CRAC 502 may use direct evaporative cooling (e.g., configured as a DEC unit), and the cooling coil 520 may be a wetted membrane providing cooling by evaporation of water as the air passes through the CRAC 502.

The amount of cooling provided can be controlled by changing the temperature of the cooling coil 520 and/or the flow through the cooling coil 520. The preferred method and the type of actuator (e.g., valve, valve motor, compressor drive, etc.) depend on the configuration of the CRAC 502.

The CRAC 502 may include a refrigerant cycle for which the cooling coil 520 is the evaporator-side heat exchanger. Cooling can be controlled, for example, by adjusting the speed of the compressor (e.g., by way of a variable speed drive) or by changing the orifice opening size of the expansion valve. In some embodiments, direct control over the expansion valve and/or the compressor speed is not provided by the CRAC 502, and the cooling is controlled indirectly by providing a supply temperature setpoint for the temperature leaving the CRAC 502 and/or a flow setpoint for the supply fan 518. Providing a temperature setpoint may cause the CRAC 502 to change the internal pressures of the refrigerant and, in turn, raise or lower the temperature of the evaporator and cooling coil 520. Temperature setpoints can be raised when cooling demands are low and can lead to energy savings resulting from decreased pressure across the compressor. Alternatively, during time periods of high computational demand, the temperature setpoint may be lowered, allowing for computing devices to reach maximum computational throughput or even allowing for overclocking of the computing devices.

In a CRAH configuration, cooling can be controlled, for example, by adjusting the flow of chilled water through the cooling coil 520 (e.g., by way of a ball valve). In some embodiments, direct control of the water valve is not provided by the CRAC 502, and the cooling is controlled indirectly by providing a supply temperature setpoint for the temperature fo air leaving the CRAC 502. A proportional-integral-derivative (PID) control loop may modulate the valve of the cooling coil 520 to maintain the desired supply temperature setpoint. Similar to the direct expansion configuration described above, the desired leaving air temperature can be modified according to the current and/or predicted computational demand. While cooler air temperatures may allow for higher computational throughput, warmer air temperatures may allow for the supply water temperature of the chiller (or similar device) cooling the water to commensurately raise their operating temperature thereby operating more efficiently.

In a DEC configuration, cooling can be controlled, for example, by turning on or off the water flow that wets the evaporative membrane. In some embodiments, evaporative cooling is binary (e.g., on or off), and a supply air temperature can act as a threshold beyond which evaporative cooling is turned on. In some embodiments, a DEC unit includes multiple evaporative membranes with individualized water flow control, allowing for some level of continuous control.

In some embodiments, the CRAC 502 includes an outdoor air damper upstream of the supply fan 518. The outdoor air damper may be used to mix outdoor air with the return air from the hot air return 510 and exhaust some of the return air. The servers 512a-d may be configured to operate at relatively hot temperatures (e.g., 50° C., 60° C., etc.), causing the return air to be elevated beyond temperatures typical of an office building. With high return air temperatures, the outdoor air is often cooler than the return air, and significant energy savings can be realized by pulling fresh outdoor air into the CRAC 502. In some embodiments, the CRAC 502 is disposed at the exterior wall of the data center environment 500, and no ductwork is required to bring in outdoor air and exhaust return air. In some embodiments, the ductwork provides a path for the outdoor air to reach the CRAC 502 and for exhaust air to leave the data center environment 500.

The racks 504 may include a number of computers (e.g., the servers 512a-d). The racks 504 may include a rack fan 514 to draw air across the CPUs (e.g., and their heat exchangers). Alternatively or additionally, the servers 512a-d may include individual CPU fans to control the CPU temperature that draw air through the racks 504. In some embodiments, the racks 504 may rely on a containment method such that the supply fan 518 forces cool air through the racks 504.

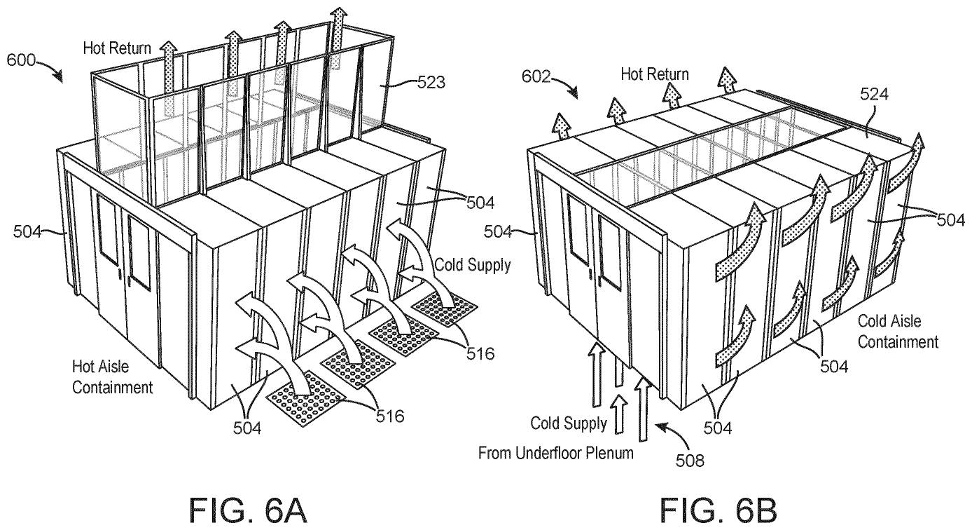

FIGS. 6A and 6B illustrate two different containment methods utilized by data centers. A rack aisle 600 is shown to use hot aisle containment, according to some embodiments. Cooled air is forced (e.g., by the supply fan 518) through the perforated tiles 516 and through the racks 504. A barrier 522 is used to prevent hot return air from mixing with cooled supply air before entering the hot air return 510. A rack aisle 602 is shown to use cold aisle containment, according to some embodiments. Cooled air is forced (e.g., by the supply fan 518) through the perforated tiles 516 from the under-floor plenum 508 into the cold aisle between racks 504. A ceiling barrier 524 is used to ensure that cooled supply air is forced through the racks and does not mix with hot return air. The hot air return 510 may be the space outside of the rack aisle 602.

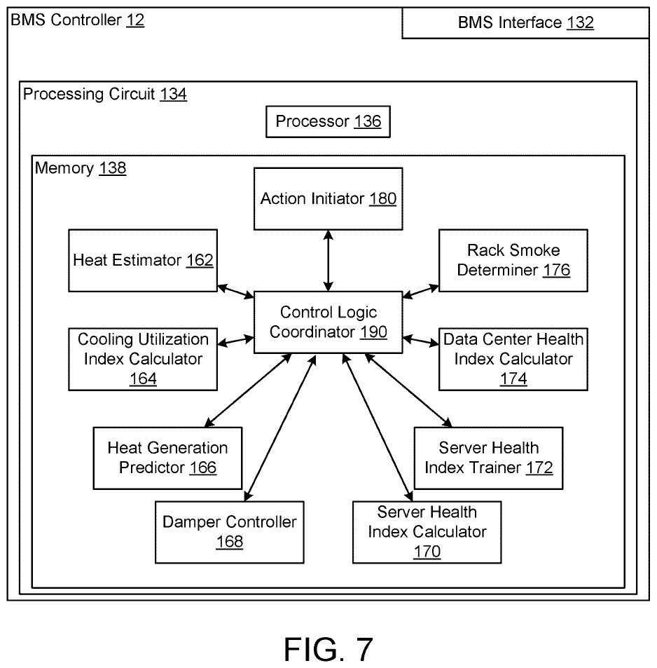

In some embodiments, a BMS controller 12 is configured to control and/or monitor a data center (e.g., data center environment 500). Some embodiments of the current disclosure include instructions stored in memory 138 that cause the processor 136 to perform control and/or monitoring operations. While FIG. 7 shows the control functionality being implemented within the BMS controller 12, it is contemplated that the data center monitoring instructions could be distributed over several discrete hardware components and/or executed by one or more processors. Any number of instructions (e.g., operations) may be distributed on multiple computers (e.g., nodes, etc.) within a cloud computing architecture. For example, the instructions of the damper controller 168 may be stored in and executed on the BMS controller 12 or another edge device, while the cooling utilization index calculator 164 may be stored in and executed in the cloud computing architecture.

FIG. 7 shows the BMS controller 12 configured to control and monitor a data center environment 500 according to some embodiments. The BMS controller may include a control logic coordinator 190, a heat estimator 162, a cooling utilization index calculator 164, a heat generation predictor 166, a damper controller 168, a server health index calculator 170, a server health index trainer 172, a data center health index calculator 174, a rack smoke determiner 176, and an action initiator 180.

In some embodiments, the BMS controller 12 provides enhanced control and monitoring functionality for racks (e.g., rack 504) with temperature telemetry. Temperature sensors can be attached (e.g., coupled to, etc.) the rack directly upstream of the heat generating computing devices and downstream of the heat generating devices with respect to the direction of air flow. Rack temperature sensors facilitate at least generating individualized (e.g., rack-level) metrics and control leading to efficiency gains for the data center as a whole.

Often computer racks do not include integrated temperatures sensors. The data center industry has focused on the performance of groups of racks, for example, by placing temperature sensors in the supply air and return air from each aisle. By aggregating groups of racks the data center, system engineers have avoided measurement inaccuracies due to localized air flow patterns and turbulent air flow. This design pattern has been reinforced by the simplicity and cost benefits of not including additional sensors. Moreover, IT systems controlling the computing devices have relied on onboard temperature sensors monitoring temperatures of components of the computers (e.g., CPUs, GPUs, etc.). Onboard temperature telemetry is often not shared with external systems in fear of using network bandwidth and opening security vulnerabilities.

The systems and methods described herein may forgo attempting to receive measurements from onboard or on-chip temperature sensors and instead facilitate rack level control by way of rack-level air temperature sensors (e.g., fixed to the rack). Advanced monitoring can provide site operators insight into current operations and facilitate allocation of computational tasks across servers, scaling of computational devices by efficient placement of new computers installed in racks, and minimize downtime by tracking wear on the equipment. Additionally, individual air flow control devices at the rack level (e.g., rack-specific dampers, fans, etc.) allows air flow to be directed through racks at flow rates commensurate with heat generation, thereby increasing the cooling system temperature differential and overall efficiency.

Systems and methods described herein can overcome measurement inefficiencies by using multiple temperature sensors and/or by judicious placement of the temperature sensors within the air stream. For example, temperature outliers may not be used while calculating monitoring metrics or for performing control. Air flow through the rack can be modeled (e.g., with computational fluid dynamics) and sensors can be placed at locations within the rack that are most beneficial to estimating the total heat generated by the rack. Accurate estimates of the leaving air temperature, air flow, and heat generation can be obtained using the temperature sensors. Additionally, the systems and methods described herein provide more granular (e.g., rack level) air flow control using the rack-specific air flow control devices. Relative to conventional data center HVAC systems, the more granular temperature measurements and more granular air flow control provided by the systems and methods of the present disclosure combine to provide a synergistic effect of enabling rack level temperature monitoring and the ability to act upon rack level temperature measurements to adjust the air flow and/or heat removal provided by the HVAC system at each rack individually.

The control logic coordinator 190 may be configured to control the timing and flow of data through the other circuitry in the BMS controller 12 to monitor and/or control the data center environment 500. For example, the control logic coordinator 190 may cause the modules or circuits to execute in a specific order to perform the function to control and/or monitor the data center environment 500. In some embodiments, the control logic coordinator 190 may route the information and/or outputs of other modules that are dependent on the information or use the information as an input.

In some embodiments, the heat estimator 162 is configured to estimate (e.g., calculate, determine, etc.) the amount of heat transferred from the computers and other peripheral devices of a computer rack 504 to air flowing through the computer rack 504. For example, the heat transfer may be estimated using two temperature measurements: one entering the computer rack 504 (Tᵢₙ) and one exiting the computer rack 504 (Tₒᵤₜ). Heat transfer may be determined using a product of the mass flow m, the specific heat of air, and the temperature difference between the exiting temperature and the entering temperature:
\dot{Q}=c\dot{m}(Tₒᵤₜ−Tᵢₙ), or in terms of volumetric flow \dot{v} and imperial units:

$$\dot{Q} = 500 [ \frac{BTU}{cfm \cdot ° F .} ] \dot{v} ( {T}_{out} - {T}_{in} ) .$$

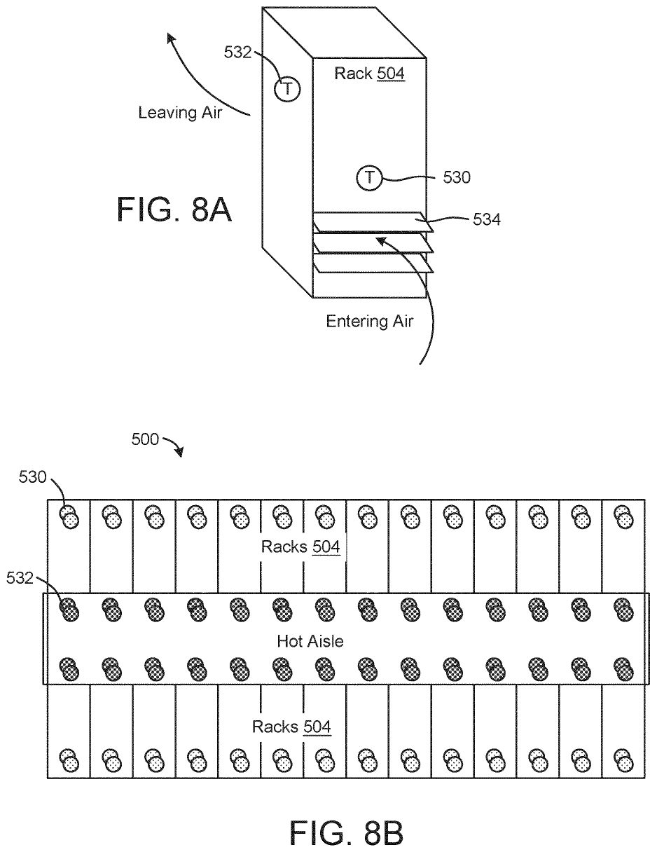

FIG. 8A shows a rack 504 with integrated air temperature sensors according to some embodiments. Air entering the rack 504 may be incident on an inlet air temperature sensor 530. The inlet air temperature sensor 530 may be used for Tᵢₙ in the equations herein. In some embodiments, more than one inlet air temperature sensor 530 is used to allow for averaging to reduce measurement error (e.g., caused by temperature gradients along the height of the rack 504). In some embodiments, the inlet air temperature sensor 530 is placed at a location where the temperature is known to represent the inlet air temperature as used in the equations. For example, the inlet air temperature sensor 530 may be placed between the midpoint and the top of the rack 504, where the temperature measured is indicative of the average inlet temperature. Air leaving the rack 504 that has been heated by heat transfer from the computers may be incident on an outlet air temperature sensor 532. The outlet air temperature sensor 532 may be used for Tₒᵤₜ in the equations herein. In some embodiments, the outlet air temperature sensor 532 is placed at a location where the temperature is known to represent the outlet air temperature as used in the equations. For example, the outlet air temperature sensor 532 may be placed between the midpoint and the top of the rack 504, where the temperature measured is indicative of the average outlet temperature. The temperature sensors 530 and 532 may be fixed to (e.g., attached to, disposed upon, etc.) the rack 504.

In some embodiments, dampers (e.g., dampers 534) can be placed facing the cold aisle (e.g., an inlet area) and/or facing the hot aisle (e.g., an outlet area). Dampers 534 can be used to adjust (e.g., control, etc.) the amount of air passing through the rack 504. For example, the dampers may be actuated by a motor that changes the damper angle and thus adjusts resistance to the air flowing through the rack 504. The dampers 534 may be adjusted by a PID controller to maintain an output air temperature setpoint. In some embodiments, the dampers 534 may be configured to open in the event of a failure (e.g., power outage, control error, etc.). For example, a spring may cause the dampers 534 to open if there is no longer power to the actuating motor or if a coupling between the motor and damper has failed. A thermal fuse may also be used to cause the dampers to open (e.g., by activating a motor) if a temperature limit of the fuse is exceeded. Additionally or alternatively, the damper control may open the damper if any of the information used to determine a position (e.g., adjust, control, etc.) for the damper becomes unreliable (e.g., out of range, in a fault condition, etc.).

As shown in FIG. 8B, inlet and outlet temperature sensors can be placed on, in, or near each rack 504 in the data center environment 500. Individual temperature sensors can be used to calculate metrics related to an individual rack 504. In some embodiments, racks owned and/or used by the same customer may not receive individual temperature sensors and metrics may be aggregated for a number of the racks of the same customer.

The cooling utilization index calculator 164 may use the estimated heat transferred into the air (e.g., heat generation by the computers of the rack 504) to calculate a cooling utilization index (CUI). The CUI may indicate the fraction of available cooling being used by a computer rack 504 and likewise may indicate the remaining available cooling for a rack 504. In some embodiments, several CUIs are calculated. For example, a CUI may be the ratio of the cooling provided to the rack 504 (e.g., heat transferred into the air from the rack 504) to the total cooling produced by the CRACs 502 serving the data center or portion of the data center,

$${CUI}_{1 , i} = \frac{{\dot{Q}}_{rack , i}}{c {\dot{m}}_{CRAC} ( {T}_{in , CRAC} - {T}_{out , CRAC} )} .$$

\dot{Q}_{rack,i} may refer to the heat transfer from the ith rack 504 to the air, \dot{m}_{CRAC} may refer to the total mass flow through the CRAC 502, T_{in,CRAC} may refer to the return air temperature (e.g., air temperature entering the CRAC 502), and T_{out,CRAC,} may refer to the supply air temperature (e.g., air temperature leaving the CRAC 502). CUI₁ may be useful for billing tenants for cooling.

In some embodiments, the cost of providing cooling to the racks is divided among users of the data center according to CUI₁. For example, the cooling utilization index calculator 164 may be configured to allocate power (e.g., electrical power) used by the CRAC 502 to a rack 504 by multiplying the energy use by the CUI₁. The cooling utilization index calculator 164 may generate a report or indication of the allocated power that can be communicated to the owner or user of the rack 504 (e.g., by the 504). Suggestions to reduce energy use (e.g., shifting operating hours, increasing computational efficiency, rearranging computing devices among different racks etc.) can be provided with the report or indication, thereby incentivizing or causing tenants to decrease energy usage. The allocated power may multiplied by an electrical rate to determine a current cost of cooling (e.g., monies per unit of time). In some embodiments, the allocated power or the cost of the allocated power is summed (e.g., by integration) over a time period (e.g., month, year, etc.). Different levels of granularity can be provided by summing the allocated power or cost over different time periods.

In some embodiments, the temperature leaving the CRAC 502 is estimated by one or more temperatures of air entering a rack 504 (e.g., as measured by a temperature sensor fixed to the rack 504), and/or the temperature entering the CRAC 502 is estimated by one or more temperatures of air leaving a rack 504 (e.g., as measured by a temperature sensor fixed to the rack 504). A CUI may be the ratio of the cooling provided to the rack 504 (e.g., heat transferred into the air from the rack 504) to the maximum cooling that could be delivered to the rack 504 at the current temperatures,

$${CUI}_{2 , i} = \frac{{\dot{Q}}_{r a ck , i}}{c {\dot{m}}_{rack , max} ( {T}_{in , rack , i} - {T}_{out , rack , i} )} .$$

\dot{m}_{rack,max} may refer to the maximum flow of air that can travel through the rack 504. CUI₂ may be useful for determining an amount of cooling that remains available to the rack 504. For example, if additional computation is done in the computers of this rack 504, CUI₂ can help determine if there are enough cooling resources available.

In some embodiments, CUI₂ represents a current rack utilization rate that can be provided to a client (e.g., customer, tenant, etc.) system for display or for use in automatically allocating new computational tasks to particular racks. For example, each client may use an IT resource manager that processes incoming tasks and assigns them to a computer. The IT resource manager may be configured to use the CUI₂ and assign the tasks to in to maximize computational throughput. New tasks may be assigned to computers in racks operating near the middle of their capacity range, for example, rather than a nearly idle rack or a rack that is already stressed and could result in increased CPU temperatures. The cooling utilization index calculator 164 may provide a recommend rack within which next tasks should be allocated based on the cooling utilization index.

In some embodiments, a maximum output temperature from the rack (e.g., maximum safe operating temperatures of the computer, etc.) may be used in place of T_{out,rack,i}. A CUI may be the ratio of the cooling provided to the rack 504 (e.g., heat transferred into the air from the rack 504) to the maximum cooling that could be delivered to the rack 504 at the minimum input temperature (e.g., minimum supply from the CRAC 502) and the maximum output temperature from the rack 504 that would still be indicative of reliable computer operation,

$${CUI}_{3} = \frac{{\dot{Q}}_{r a ck , i}}{c {\dot{m}}_{rack , max} ( {T}_{out , rack , max , i} - {T}_{out , CRAC , min} )} .$$

T_{out,CRAC,min} may refer to the minimum temperature of air that can be supplied by the CRAC 502, and T_{out,rack,max,i} may refer to the maximum temperature of air that can safely leave the rack 504 (e.g., before risking damage to the computers and/or the cooling equipment). CUI₃ may also be useful for determining the amount of cooling that remains available to the rack 504. For example, if additional computation is done in the computers of this rack 504, CUI₃ can also help determine if there are enough cooling resources available.

In some embodiments, the CUI may be combined with a power measurement. Combining the CUI and the power may provide a better indication of the amount of computational resources that are still available in a rack 504. In some embodiments, the CUI may be averaged over a time window (e.g., a minute, an hour, a week) to provide the typical utilization over a time period. The combined CUI/power index may represent the factor (e.g., power or cooling) that is currently most limiting to future use of the rack. For example, the cooling utilization index calculator 164 may calculate the CUI and a ratio of electrical power used by the computing devices in the rack to the total power the rack can supply (e.g., the rack's power rating) and report the maximum of the CUI and the power utilization ratio as the combined CUI/power index.

In some embodiments, the BMS controller 12 is configured to generate a user interface displaying the CUI or power utilization ratio indices. The user interface may include a dashboard allowing the user to sort racks and/or computers according to the to the index. Indices may be overlaid on a floor plan of the data center provide the user with a summary view of data center HVAC operations and allowing the user to plan expansions. In some embodiments, the BMS controller 12 is configured to store a time series of the CUI or power utilization ratio. Alternatively, individual calculations of the CUI or power utilization ratio can be time stamped and communicated to remote applications 18 for time series storage. The user interface may be configured to display the time series data of the CUI or power utilization ratio and/or average the CUI or power utilization ratio over different time scales.

In some embodiments, the heat generation predictor 166 is configured to predict (e.g., estimate a future value of) the heat generated by the computers of a computer rack 504 and/or the heat transferred from the computers of the computer rack 504 to the air. The heat generation predictor 166 may use various discrete and/or continuous time equations to predict the heat transferred into the air. For example, the heat generation predictor 166 may use an auto-regressive (AR) model:

$${\dot{Q}}_{k + 1} = {a}_{1} {\dot{Q}}_{k} + {a}_{2} {\dot{Q}}_{k - 1} + {a}_{3} {\dot{Q}}_{k - 2} + … + {bP}_{k} .$$

to predict future values of the heat transfer, where k may refer to the time index and Pₖ is the current power being used by the computers of the rack 504. As shown in the autoregressive model above the predictions may be based on a measurement of the computer power use. Other models may also be used. For example, the autoregressive model may use measurements of heat generation (e.g., heat entering the air flow) only. In some embodiments, the current power being used by the computers of the rack 504 is estimated using the computational load or another suitably correlated variable. The auto-regressive model may be of any order (e.g., any number of coefficients a). To predict more than one step into the future, one step can be predicted and then the one-step-ahead prediction can be substituted back into the AR equation to calculate the two-step-ahead prediction. In some embodiments, a physics-based dynamic systems model can be used to predict the output power. For example, a first-order equation that depends on the processor temperature and the air temperature may be used:

$${\dot{Q}}_{k + 1} = {a}_{1} \dot{m} ( {T}_{CPU , k} - {T}_{in , k} ) + {bP}_{k} .$$

where a₁ may refer to a term that combines the effectiveness of the CPU heat exchanger and the heat capacity of air.

Power used by a computer rack or group of racks can be similarly predicted by the heat generation predictor 166. In some embodiments, a second autoregressive model is used to predict the power usage, thereby allowing the prediction of the heat generation and the power usage to deviate. Advantageously, using a separate prediction model for the power allows the heat generation predictor 166 to account for lag time between computational throughput (e.g., indicated by increased power use) and the heat entering the air flow. In some embodiments, the power is equated to the heat generation (e.g., a single predictor is used).

Predictions of heat generation may be used to determine predictive cooling utilization indices and/or power utilization ratios. To determine the predictive cooling utilization index any of the equations described above may applied using the predictive value of the heat generation. Similarly, predicted values of the power use can be used to determine the power utilization ratio.

Predictions of heat generation can be used by the by the BMS controller 12 to control the cooling systems (e.g., the CRAC 502, etc.). In some embodiments, the BMS controller 12 is configured to perform preemptive actions based on the predicted heat generation. For example, the BMS controller 12 may initialize (e.g., start, etc.) a second CRAC 502 (e.g., a CRAC, CRAH, DEC, or similar device) or stage thereof in response to a predicted increase in the heat generation prior to the increase occurring. Predictions can additionally or alternatively be used in order to perform predictive control of the cooling equipment. In some embodiments, the BMS controller 12 is configured with model predictive control (MPC). The MPC algorithm selects an optimized set of control actions for the cooling equipment such as which equipment should operate and at what setpoints (e.g., air flow, temperature, etc.) for the prediction of the heat generation.

In some embodiments, the damper controller 168 is configured to control the position of a damper 534 that modulates the amount of air flowing through a rack 504. The damper controller 168 may control the position based on any suitable setpoint. For example, the damper position may be configured to control the temperature of the air leaving the rack 504, the temperature of CPUs in the rack 504 (e.g., average temperature, maximum temperature, etc.). In some embodiments, a cascaded control loop may be used, where the temperature is controlled by modulating a flow setpoint or a flow setpoint may be chosen based on the current computation load. The damper position may be controlled to cause the flow through the rack 504 to be the flow setpoint.

The damper controller 168 may control the damper position using any suitable control logic. In some embodiments, a feedforward controller (e.g., function, lookup table, etc.) that maps the current value of the computational load, computer temperature, heat transfer, output air temperature, etc. to a damper position could be used. In some embodiments, feedback control is provided. For example, a PID controller or PI controller (e.g., the derivative term is set to zero) could be used to provide damper control. Additionally or alternatively, models of the heat transfer (e.g., from the heat generation predictor 166) could be used to provide predictive control.

The computations performed by a computer in the computer rack 504 may change abruptly, causing a rapid increase in the amount of cooling needed by the computer. It may be desirable to control the cooling of the computer rack such that additional cooling is available (e.g., a cooling utilization index that is less than 100%). In some embodiments, parameters of the control strategy used to control the exiting temperature (e.g., by adjusting the damper position) are adjusted based on the cooling utilization index. For example, the PI parameters may be tuned to react quicker if the cooling utilization index is near 100%. Additionally or alternatively, the setpoint for the temperature of the air leaving the rack 504 may be chosen to cause the cooling utilization index to be less than 100% or indicative of additional capacity (e.g., the cooling utilization index may be 50% or 60%).

In some embodiments, the server health index calculator 170 is configured to calculate a server health index (SHI). The SHI may be representative of the remaining life of a computer or computers within a rack 504 of a data center. A high SHI indicates that failure may be a long time into the future; a low SHI may indicate that a failure is imminent. In some embodiments, the SHI may map to the remaining lifetime of the computer on a logarithmic scale to give a more detailed assessment of remaining lifetime when failure is expected soon. For example, SHI scores between 80-100 may be indicative of 1-5 years of remaining life and scores between 60-80 may be indicative of 6-12 months of remaining life.

In some embodiments, the SHI is a function of a measured temperature of the computer (e.g., of the CPU, the memory, exiting air temperature, etc.), a CPU usage (e.g., a fraction of available CPU cycles used), and a RAM usage (e.g., fraction of available memory currently allocated). For example, the SHI may be calculated by:

$$SHI = 1 - \frac{1}{{c}_{EOL}} \int [ {{w}_{T} ( T - {τ}_{T} )}^{+} + {{w}_{CPU} ( {u}_{CPU} - {τ}_{CPU} )}^{+} + {{w}_{RAM} ( {u}_{RAM} - {τ}_{RAM} )}^{+} ] dt ,$$

where w may refer to a weighting (e.g., importance) of the temperature component, CPU component, or RAM component, t may refer to a threshold, and u may refer to a usage. The function (x)⁺ may represent the function max (x,0), and c_{EOL} may refer to a value of the integral associated with the end of life of the computer. The SHI may also depend on the cooling utilization index. The cooling utilization index may be indicative of operating the computers at high temperatures and/or high air flow, which may lead to component failures and be incorporated into the SHI calculation using a term similar to the temperature component, the CPU utilization component, and/or the RAM component.

In some embodiments, the server health index trainer 172 may train (e.g., determine, etc.) parameters for a machine learning model that calculates the SHI and/or the remaining useful lifetime of a computer or computers. For example, the server health index trainer 172 may determine values for the parameters c_{EOL}, w_{T}, w_{CPU}, w_{RAM}, τ_{T}, τ_{CPU}, and τ_{RAM} of the SHI equation above based on data associated with computers that failed. The server health index trainer 172 may perform a least squares regression problem (e.g., nonlinear or linear) to calculate the parameters of the model. Depending on the model, one of various least squares optimization algorithms can be performed to find the best fit parameters. For example, quadratic programming, the Levenberg-Marquardt method, stochastic gradient descent, the pseudo-inverse, etc. could all be applied to calculate the parameters of the SHI model.

In some embodiments, the SHI model may be a neural network, and the server health index trainer 172 may perform stochastic gradient descent to calculate the parameters of the neural network. The SHI model may be a regression-type model that determines the remaining lifetime of the computer. Additionally or alternatively, the SHI model may be a classification-type model that determines the remaining lifetime of the computer from a number of different predefined ranges (e.g., within the week, within the month, within the quarter, within the year, etc.).

The server health index trainer 172 may acquire (e.g., collect, receive, etc.) a set of training data to use in training the SHI model (e.g., by least squares, or by training the neural network). The set of training data may include historical operations (e.g., temperature, CPU usage, RAM usage) of one or more failed computers. For each failed computer of the training set, a training sample can be created. A training sample may include the historical operations up to a training point in time and the amount of time after the training point in time that the computer failed. Multiple training data can be created from one failed computer by selecting different training points in time (e.g., each month, every 3 months, etc.).

The server health index trainer 172 may fit the parameters of the SHI model (e.g., c_{EOL}, w_{T}, w_{CPU}, w_{RAM}, τ_{T}, τ_{CPU}, and τ_{RAM}) to cause the output of the SHI model to match the amount of time after the training point in time that the computer failed by optimizing a squared error between the remaining lifetime predicted by the SHI model and the amount of time after the training point in time that the computer failed. Alternatively, if the SHI model is a neural network model, the loss function during training may include the difference between the remaining lifetime predicted by the SHI model and the amount of time after the training point in time that the computer failed. A neural network may also be trained to classify the remaining lifetime of the computer into a number of different predefined ranges (e.g., within the week, within the month, within the quarter, within the year, etc.). Such classifiers may be trained using a categorical cross-entropy cost.

In some embodiments, the data center health index calculator 174 combines the data from the racks 504, CRACs 502, and/or computers of the data center and determines a score for the entire center. The data center health index calculator 174 may compute an average SHI of the computers within the data center. For example, the data center health index calculator 174 may calculate the average of all of the computers, the average of the worst 10% of the computers, the average of the worst 5% of the computers, etc. In some embodiments, the data center health index calculator 174 may additionally include health indices of the cooling equipment; for example, a chiller performance index and/or the CUI can be included in the data center health index.

In some embodiments, the rack smoke determiner 176 is configured to determine a rack 504 that is causing a smoke-generating event. For example, sampling points for an aspiration smoke detector (ASD) may be disposed in the ductwork of one or more CRACs 502, advantageously allowing one ASD to monitor a large number of racks 504. In the event that smoke is detected in the ducts, temperature sensors on the racks 504 can be used by the rack smoke determiner 176 to localize the cause of the event (e.g., determine the affected rack). In addition, the timing of when various sampling points of an ASD first detected smoke can be used by the rack smoke determiner 176 in order to localize the cause. The rack 504 and/or area affected by the smoke event is likely to have elevated temperatures and/or temperature sensors that are no longer reporting measurements. The rack smoke determiner 176 and/or the ASD may be configured to generate an audible alarm or indication of a detection.

Although the rack smoke determiner 176 is described as operating with an ASD, it is understood that other sensing devices and/or detection technology can be used in order to detect overheating events and localize such events. For example, one or more chemical sensors may be used in the air stream. Chemical sensors can operate as “electronic noses” capable of detecting atypical chemicals in the airstream that may be indicative of overheating and/or smoke. Similarly, it is understood that the rack smoke determiner 176 may use sensors configured to detect other chemicals, air contamination, etc. that are indicative of smoke, fire, or an overheating event. For example, sensors in operation with the rack smoke determiner 176 may be configured to detect volatile organic compounds and other gases that are released when certain materials are heated. The sensors in operation with the rack smoke determiner 176 may be configured to detect by-products of thermal decomposition; other combustion by-products that may form before smoke; and burn off of dust, oil, or other residue on the overheating surface when equipment overheats.

In some embodiments, the action initiator 180 is configured to initiate an action based on any of the calculations described herein. An action that the action initiator 180 may initiate can be based on the score, calculation, or event that causes the action initiator 180 to activate. The various actions that may be taken are described in more detail in the following sections. Actions can include affecting the control the system (e.g., providing more/less cooling). Actions can include generating an indication of a stressed system (e.g., a system that has high air temperature exiting the rack, high cooling or power utilization, etc.). For example, alarms or notifications can be generated on a user interface, emailed or sent via text to an operator. Actions can include displaying the indices (e.g., utilization, health indices, etc.) on a user interface, for example, on a floor plan, building information modeling (BIM) model, or overhead view of the data center. In some embodiments, the indices are communicated from the BMS controller 12 to the rack (e.g., for presentation on a rack mounted display).

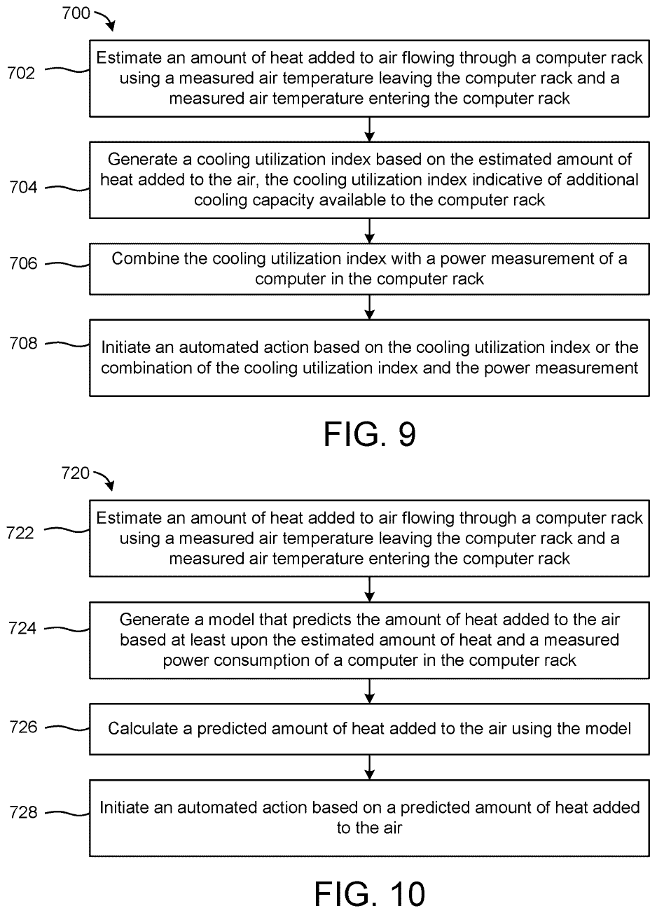

FIGS. 9-14 show flows of operations describing how temperature sensors mounted to the racks configured to accurately measure temperatures within the airflow through a rack can be used to improve monitoring and control of data center cooling systems. Such sensors can provided metrics that facilitate actions and control increasing the efficiency of the data center.

### Tenant Cooling Utilization Index

FIG. 9 shows a flow of operations 700 for initiating an automated action based on a CUI calculation according to some embodiments. The flow 700 includes estimating an amount of heat added to air flowing through a computer rack using a measured air temperature leaving the computer rack and a measured air temperature entering the computer rack in operation 702. The heat estimator 162 may estimate (e.g., calculate, determine, etc.) the amount of heat transferred from the computers and other peripheral devices of a computer rack 504 to air flowing through the computer rack 504. For example, the heat transfer may be estimated using two temperature measurements: one entering the computer rack 504 (Tin) and one exiting the computer rack 504 (Tout). Multiple temperature sensors may be used to reduce noise due to turbulent or otherwise unpredictable flow within the computer rack 504. Alternatively, the rack can be modeled to determine locations where a temperature sensor would consistently measure a temperature indicative of the heat entering the air for a variety of flow conditions and computer installations. The heat estimator 162 may calculate the heat transfer using a product of the mass flow m, the specific heat of air c, and the temperature difference between the exiting temperature and the entering temperature as shown in:
\dot{Q}=c\dot{m}(Tₒᵤₜ−Tᵢₙ), or in terms of volumetric flow v and imperial units:

$$\dot{Q} = 500 [ \frac{BTU}{cfm \cdot ° F .} ] \dot{v} ( {T}_{out} - {T}_{in} ) .$$

In some embodiments, the flow 700 includes generating a cooling utilization index based on the estimated amount of heat added to the air, and the cooling utilization index is indicative of additional cooling capacity available to the computer rack in operation 704. The cooling utilization index calculator 164 may use the estimated heat transferred into the air calculated by the heat estimator 162 to calculate a cooling utilization index (CUI). The CUI may indicate the fraction of available cooling being used by a computer rack 504 and likewise may indicate the remaining available cooling for a rack 504. In some embodiments, several CUIs are calculated for a number of racks 504. For example, CUI₁ may be the ratio of the cooling provided to the rack 504 (e.g., heat transferred into the air from the rack 504) to the total cooling produced by the CRACs 502 serving the data center or a portion of the data center and may be useful for billing tenants for cooling. CUI₂ may be the ratio of the cooling provided to the rack 504 (e.g., heat transferred into the air from the rack 504) to the maximum cooling that could be delivered to the rack 504 at the current temperatures. CUI₂ may be used to determine if there are enough cooling resources available in the rack 504 if more computational load is transferred to the computers of the rack 504. CUI₃ may be the ratio of the cooling provided to the rack 504 to the maximum cooling that could be delivered to the rack 504 at the minimum input temperature (e.g., minimum supply from the CRAC 502) and the maximum output temperature from the rack 504 that would still be indicative of reliable computer operation. CUI₃ may also be useful for determining an amount of cooling that remains available to the rack 504. For example, if additional computation is done in the computers of this rack 504, CUI₃ can also help determine if there are enough cooling resources available.

The flow 700 may include combining the cooling utilization index with a power measurement of a computer in the computer rack in operation 706. Combining the CUI and the power may provide a better indication of the amount of computational resources still available in a rack 504.

In some embodiments, the flow 700 may include initiating an automated action based on the cooling utilization index or the combination of the cooling utilization index and the power measurement in operation 708. The cooling utilization index may be indicative of strained cooling equipment, not enough cooling available for an individual rack 504, and/or the amount of cooling a tenant of the data center uses. The action initiator 180 may initiate an action capable of mitigating an effect of such conditions. For example, the action initiator 180 may cause a second source of cooling to be provided to the computer rack (e.g., by sending a request or other electronic control signal to a controller for the second source of cooling). The rack 504 may include a provision for direct liquid cooling that can be pumped to the processors to exchange heat between the computers of the rack 504 and the chilled water system of a central (e.g., chiller) plant. Additionally or alternatively, the action initiator 180 may increase the air flow into the rack 504 to provide additional cooling. The action initiator 180 may generate an indication of computers that can be moved from a second computer rack to the computer rack 504. Consistently high CUI may indicate that a specific rack is overused, and computers should be installed in another rack with less utilization. Similarly, the action initiator 180 may move computational load from a second computer in the second computer rack to a first computer in the computer rack. In some embodiments, tenants of the data center are billed based on their utilization, and the action initiator 180 can generate a utilization report or bill including a cost that is based on the CUI (e.g., as compared to the CUI of other tenants). The utilization report can indicate the tenants energy use and provide feedback that could increase overall energy efficiency. In some embodiments, the automated action includes displaying the CUI on a user interface.

In some embodiments, the CUI is used to change parameters of a controller of the cooling system (e.g., within the damper controller 168 of the BMS controller 12). The CUI may be used to determine one or more setpoints of the cooling system. For example, a setpoint for the temperature of supply air sent to the racks may be determined such that the CUI of the rack operates at a particular value (e.g., 60%, 70%, etc.) ensuring that there is reserve capacity available for rapid increases in heat generation due to increased computational throughput. In some embodiments, parameters of the PID or other feedback controller are based on the CUI. For example, the aggressiveness (e.g., responsivity) of the parameters may increase with increasing CUI causing the controller respond rapidly when CUI is high to avoid potential throttling.

### Heat Prediction

FIG. 10 shows a flow of operations 720 for predicting an amount of heat added to the air from a computer and/or computer rack in a data center according to some embodiments. The flow 720 may include estimating an amount of heat added to air flowing through a computer rack using a measured air temperature leaving the computer rack and a measured air temperature entering the computer rack in operation 722. The heat estimator 162 may estimate (e.g., calculate, determine, etc.) the amount of heat transferred from the computers and other peripheral devices of a computer rack 504 to air flowing through the computer rack 504. For example, the heat transfer may be estimated using two temperature measurements: one entering the computer rack 504 (Tᵢₙ) and one exiting the computer rack 504 (Tₒᵤₜ.). The heat estimator 162 may calculate the heat transfer using a product of the mass flow m, the specific heat of air c, and the temperature difference between the exiting temperature and the entering temperature as shown in:
\dot{Q}=c\dot{m}(Tₒᵤₜ−Tᵢₙ), or in terms of volumetric flow v and imperial units:

$$\dot{Q} = 500 [ \frac{BTU}{cfm \cdot ° F .} ] \dot{v} ( {T}_{out} - {T}_{in} ) .$$

In some embodiments, the flow 720 includes generating a model that predicts the amount of heat added to the air based at least upon the estimated amount of heat and a measured power consumption of a computer in the computer rack in operation 724. For example, the heat generation predictor 166 may use various discrete and/or continuous time equations to predict the heat transferred into the air. An auto-regressive (AR) model:

$${\dot{Q}}_{k + 1} = {a}_{1} {\dot{Q}}_{k} + {a}_{2} {\dot{Q}}_{k - 1} + {a}_{3} {\dot{Q}}_{k - 2} + … + {bP}_{k + 1} ,$$

may be used to predict future values of the heat transfer, where k may refer to the time index and Pₖ is the current power being used by the computers of the rack 504. Alternatively or additionally, a physics-based model:

$${\dot{Q}}_{k + 1} = {a}_{1} \dot{m} ( {T}_{CPU , k} - {T}_{in , k} ) + {bP}_{k + 1} ,$$

may be used. a₁ may refer to a term that combines the effectiveness of the CPU heat exchanger and the heat capacity of air. In some embodiments, the estimated amount of heat added to the air and/or the power of the CPUs is used to train the model. For example, system identification can be performed to determine the parameters of the AR model or the physics-based model.

The flow 720 may include calculating a predicted amount of heat added to the air using the model in operation 726. The models trained in operation 724 can, in operation 726, be used by the heat generation predictor 166 to determine future values of the amount of heat added to the air.

In some embodiments, the flow 720 may include initiating an automated action based on the prediction of the cooling utilization index or the combination of the cooling utilization index and the power measurement in operation 728. The predicted amount of heat generated may be used to determine a predicted CUI (e.g., over the next few minutes, etc.) so that a proactive action may be taken. High predicted heat generation (and thus a high predicted cooling utilization index) may be indicative of strained cooling equipment, not enough cooling available for an individual rack 504, and/or the amount of cooling a tenant of the data center uses. The action initiator 180 may initiate an action capable of mitigating an effect of such conditions before they become severe. For example, the action initiator 180 may cause a second source of cooling to be provided to the computer rack. The rack 504 may include a provision for direct liquid cooling that can be pumped to the processors to exchange heat between the computers of the rack 504 and the chilled water system of a central (e.g., chiller) plant. By predicting the heat generated within a rack valves for liquid cooling, can be preemptively actuated to ensure that liquid cooling begins to arrive at the rack 504 when it is needed. Additionally or alternatively, the action initiator 180 may increase the air flow into the rack 504 to provide additional cooling preemptively (e.g., to ensure that damper stroke times and the time required for fans to increase to operating speed do not cause overheating and limit the computational throughput of the computing devices). The action initiator 180 may also move the computational load from a second computer in the second computer rack to a first computer in the computer rack. In some embodiments, the action initiator 180 generates instructions to display the predicted heat generations in a timeseries on a user interface. Predictions can be averaged or otherwise aggregated to provide predictive utilization indices, for example, overlaid on a floorplan, BIM model, or overhead view of the data center.

Cold Aisle Containment Configuration with Damper

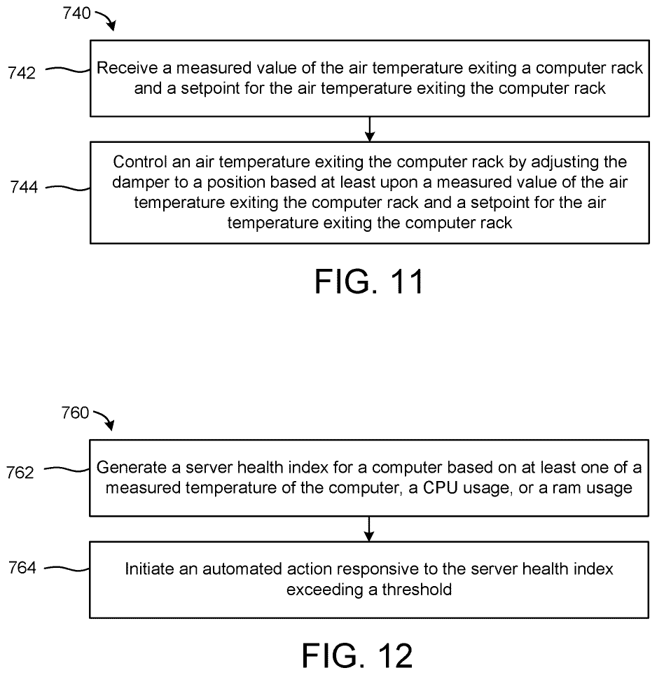

FIG. 11 shows a flow of operations 740 for controlling cooling provided to a rack 504 of a data center using dampers installed on the rack 504 according to some embodiments. The flow 740 may include receiving a measured value of the air temperature exiting a computer rack and a setpoint for the air temperature exiting the computer rack in operation 742. Air temperature exiting the rack may, for example, be measured by outlet air temperature sensor 532.

In some embodiments, the flow 740 includes controlling an air temperature exiting the computer rack by adjusting the damper to a position based at least upon a measured value of the air temperature exiting the computer rack and a setpoint for the air temperature exiting the computer rack in operation 744. The damper controller 168 may control the position based on any suitable setpoint. For example, the damper position may be configured to control the temperature of the air leaving the rack 504 and/or the temperature of CPUs in the rack 504 (e.g., average temperature, maximum temperature, etc.). In some embodiments, a cascaded control loop may be used, where the temperature is controlled by modulating a flow setpoint or a flow setpoint may be chosen based on the current computation load. The damper position may be controlled to cause the flow through the rack 504 to be the flow setpoint.

The damper controller 168 may control the damper position using any suitable control logic. In some embodiments, a feedforward controller (e.g., function, lookup table, etc.) that maps the current value of the computational load, computer temperature, heat transfer, output air temperature, etc. to a damper position could be used. The feedforward controller may also be based on a predicted value of the computational load, computer temperature, heat transfer, output air temperature, etc. to a damper position (e.g., in a model predictive control configuration). In some embodiments, feedback control is provided. For example, a PID controller or PI controller (e.g., with the derivative term set to zero) could be used to provide damper control. Additionally or alternatively, models of the heat transfer (e.g., from the heat generation predictor 166) could be used to provide predictive control. Feedback control can be combined with feedforward control, for example, by allowing the feedforward component to rapidly increase cooling in response to increased computation throughput and performing adjustments with feedback to control to the desired setpoint.

The computations performed by a computer in the computer rack 504 may change abruptly, causing a rapid increase in the amount of cooling needed by the computer. It may be desirable to control the cooling of the computer rack such that additional cooling is available (e.g., a cooling utilization index that is less than 100%). In some embodiments, parameters of the control strategy used to control the exiting temperature (e.g., by adjusting the damper position) are adjusted based on the cooling utilization index. For example, the PI parameters may be tuned to react more quickly if the cooling utilization index is near 100%. Additionally or alternatively, the setpoint for the temperature of the air leaving the rack 504 may be chosen to cause the cooling utilization index to be less than 100% or indicative of additional capacity (e.g., a supply air setpoint may be chosen to cause the cooling utilization index to operate around be 50% or 60%).

### Server Health Index

FIG. 12 shows a flow of operations 760 for initiating an automated action based on a server health index (SHI) according to some embodiments. The flow 760 may include generating a server health index for a computer based on at least one of a measured temperature of the computer, a CPU usage, or a RAM usage in operation 762. The SHI may be indicative of the remaining useful lifetime of a computer or a set of computers in the data center. For example, the server health index calculator 170 may calculate the SHI as a function of a measured temperature of the computer (e.g., of the CPU, the memory, exiting air temperature, etc.), a CPU usage (e.g., a fraction of available CPU cycles used), and a RAM usage (e.g., fraction of available memory currently allocated) by:

$$SHI = 1 - \frac{1}{{c}_{EOL}} \int [ {{w}_{T} ( T - {τ}_{T} )}^{+} + {{w}_{CPU} ( {u}_{CPU} - {τ}_{CPU} )}^{+} + {{w}_{RAM} ( {u}_{RAM} - {τ}_{RAM} )}^{+} ] dt ,$$

where w may refer to a weighting (e.g., importance) of the temperature component, CPU component, or RAM component, t may refer to a threshold, and u may refer to a usage. The function (x)⁺ may represent the function max (x, 0) and c_{EOL} may refer to a value of the integral associated with the end of life of the computer.

In some embodiments, the flow 760 includes initiating an automated action responsive to the server health index exceeding a threshold in operation 764. The SHI may be used by the action initiator 180 to initiate one or more actions responsive to the SHI satisfying a criterion (e.g., exceeding a threshold, being within a range, etc.). The action initiator 180 may initiate an action capable of mitigating an effect of such conditions before they become severe. For example, the action initiator 180 may cause a second source of cooling to be provided to the computer rack. The rack 504 may include a provision for direct liquid cooling that can be pumped to the processors to exchange heat between the computers of the rack 504 and the chilled water system of a central (e.g., chiller) plant. Additionally or alternatively, the action initiator 180 may increase the air flow into the rack 504 to provide additional cooling. The action initiator 180 may also move computational load from a second computer in the second computer rack to a first computer in the computer rack, move a high priority task to a second computer with a better SHI, and/or move a low priority task to the computer with the poor SHI. In some embodiments, the computer with a low SHI may be proactively replaced. The action initiator 180 may cause the replacement of the computer, for example, by purchasing or creating a purchase order for a new computer. The action initiator 180 may also cause a computer (e.g., of a group of redundant computers) to be automatically configured similarly to the computer that has the low SHI. Proactively configuring a redundant computer may make replacement or failover more seamless in the event that the computer with a low SHI does fail. In some embodiments, the automated action includes displaying the SHI on a user interface, for example, overlaid on an overhead view of the data center, on a rendering from a BIM model, and/or on a floor plan.

In some embodiments, the SHI is used during the control of computer racks 504. For example, the cooling system may be configured to provide additional cooling capacity (e.g., by increasing the air flow or decreasing the supplied air temperature) to racks with computers having a low server index. The increased cooling capacity may ensure that the temperature of the computing devices do not go above the threshold value in the server health index calculation even during rapid increases in computational throughput. The cooling system is thereby configured to manage systems that may be at end-of-life until a replacement can be provisioned and installed.

In some embodiments, the SHI is combined with other indices (e.g., scores, metrics, etc.) described herein to determine an appropriate automated action to perform. For example, a high cooling utilization index may be indicative of overusing the available cooling (e.g., high CPU temperatures, etc.), potentially indicating an automated action that (i) increases the cooling available to the rack (e.g., by lowering supply temperature, increasing air flow, etc.) or (ii) decreases the computational load of the rack (e.g., by moving tasks to a different computer, computer rack, etc.). Using both the cooling utilization index and the SHI may allow for suitable selection of the two types of mitigating action. For example, if SHI is low (e.g., there is potential for a failure), it may be more appropriate to preemptively move tasks to a different computer or rack.

### Maintenance and Failure Prediction and Notification

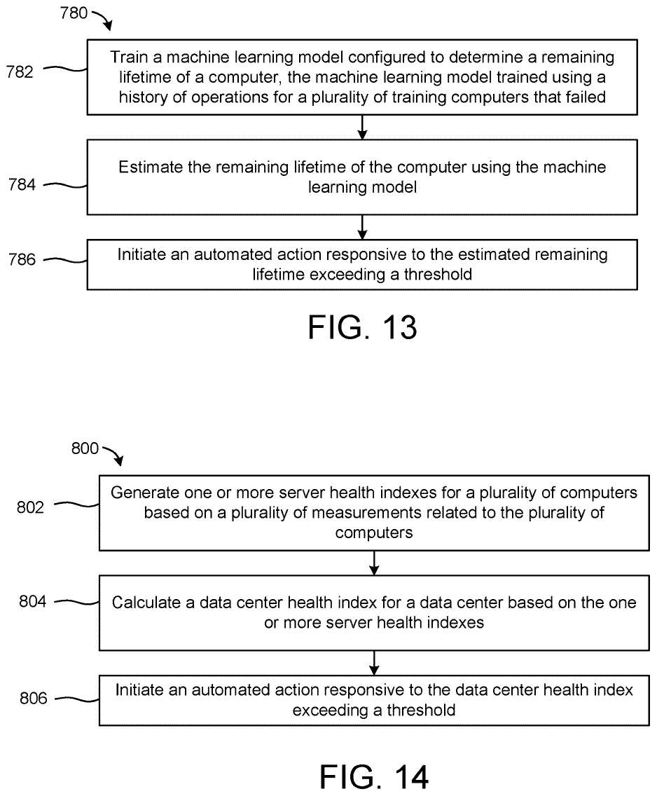

FIG. 13 shows the flow of operations 780 for training a model to calculate a value indicative of the remaining life of a computer at a data center according to some embodiments. For example, the flow 780 may train a model to calculate the SHI. Flow 780 may include training a machine learning model configured to determine a remaining lifetime of a computer, the machine learning model trained using a history of operations for a plurality of training computers that failed in operation 782. Training data may be collected from failed computers; the operational history of the failed computer may be saved and used as predictor variables during training. The server health index trainer 172 may train (e.g., determine, etc.) parameters for a machine learning model that calculates the SHI and/or the remaining useful lifetime of a computer or computers. For example, the server health index trainer 172 may determine values for the parameters c_{EOL}, w_{T}, w_{CPU}, w_{RAM}, τ_{T}, τ_{CPU}, and τ_{RAM} of the SHI equation above based on data associated with computers that failed, or a neural network may be trained by the server health index trainer 172 using stochastic gradient descent.

In some embodiments, the flow 780 includes estimating the remaining lifetime of the computer using the machine learning model in operation 784. Data can be collected for currently working computers and the expected lifetimes may be calculated. For example, the server health index calculator 170 may calculate the SHI for each server of the data center using newly collected data. In some embodiments, the remaining lifetime before maintenance is required is calculated rather than the remaining lifetime prior to failure.

In some embodiments, the flow 780 includes initiating an automated action responsive to the remaining lifetime exceeding a threshold in operation 786. The remaining lifetime prior to failure or the remaining lifetime prior to maintenance may be used by the action initiator 180 to initiate one or more actions responsive to the remaining lifetime satisfying a criterion (e.g., exceeding a threshold, being within a range, etc.). The action initiator 180 may initiate an action capable of mitigating an effect of such conditions before they become severe. For example, the action initiator 180 may cause a second source of cooling to be provided to the computer rack. The rack 504 may include a provision for direct liquid cooling that can be pumped to the processors to exchange heat between the computers of the rack 504 and the chilled water system of a central (e.g., chiller) plant. Additionally or alternatively, the action initiator 180 may increase the air flow into the rack 504 to provide additional cooling. The action initiator 180 may also move computational load from a second computer in the second computer rack to a first computer in the computer rack, move a high priority task to a second computer with a longer remaining lifetime, and/or move a low priority task to the computer with the shorter remaining lifetime. In some embodiments, the computer with a shorter remaining lifetime may be proactively replaced. The action initiator 180 may cause the replacement of the computer, for example, by purchasing or creating a purchase order for a new computer. The action initiator 180 may also cause a computer (e.g., of a group of redundant computers) to be automatically configured similarly to the computer that has the shorter remaining lifetime. Proactively configuring a redundant computer may make replacement or failover more seamless in the event that the computer with the shorter remaining lifetime does fail. In some embodiments, the action initiator generates an indication of devices to proactively replaced within a user interface, for example, overlaid on an overhead view of the data center, on a rendering from a BIM model, and/or on a floor plan.

### Data Center Health and Performance Index

FIG. 14 shows the flow of operations 800 for calculating a data center health index and initiating an automated action related to the overall health of the data center. The flow 800 may include generating one or more server health indexes for a plurality of computers based on a plurality of measurements related to the plurality of computers in operation 802. For example, the server health index calculator 170 may calculate the SHI for a number of racks 504 and/or computers (e.g., servers 512a-d) in the data center.

In some embodiments, the flow 800 includes calculating a data center health index for a data center based on the one or more server health indexes in operation 804. For example, the data center health index calculator 174 may combine several health indices and/or other metrics from the data center to calculate a combined score. The data center health index calculator 174 may calculate the average SHI of all of the computers, the average SHI of the worst 10% of the computers, the average SHI of the worst 5% of the computers, etc. In some embodiments, the data center health index calculator 174 may additionally include health indices of the cooling equipment; for example, a chiller performance index and/or the CUI can be included in the data center health index.

In some embodiments, the flow 800 includes initiating an automated action in response to the data center health index exceeding a threshold in operation 806. Data can be compared across all data centers within a portfolio and actions can be performed to improve low-scoring data centers and/or outliers. For example, several computers with a low SHI may be indicative of elevated temperatures, and the action initiator 180 may cause an upgrade of the cooling equipment at the data center. For example, a technician can be automatically scheduled to determine which of the equipment is responsible for the low scores. In some embodiments, the action initiator 180 may move tasks between data centers. For example, a high priority task may be moved from a poorly performing data center to a high performing data center, or a low priority task may be moved from a high performing data center to a low performing data center. The action initiator 180 may automatically schedule a site visit for a person that manages the portfolio of data centers; for example, a site visit for an energy executive may be scheduled.

### Duct Detector

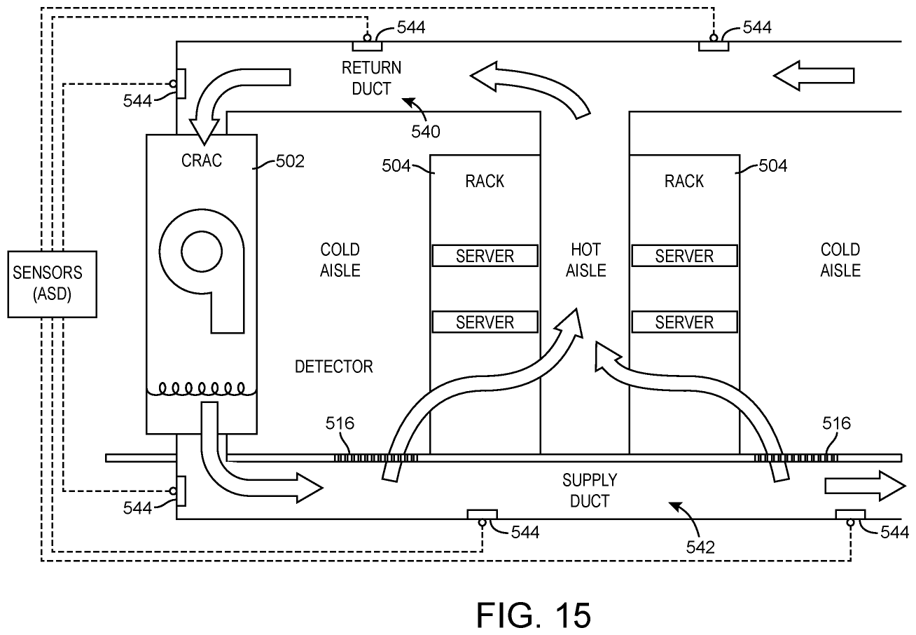

FIG. 15 shows a data center environment 500 according to some embodiments. The data center environment 500 may be configured with hot aisle containment and use ductwork to supply cooled air to the racks 504. In some embodiments, a supply duct 542 is configured to carry cooled air from the CRAC 502 to the racks 504. In some embodiments, a return duct 540 is configured to carry the air heated by the computers from the racks 504 back to the CRAC 502. The high speed of the air flow within a data center environment can cause standard smoke alarms to not alarm and/or alarm too late. Aspiration smoke detectors (ASDs) may be used instead of typical smoke alarms. ASDs are more costly to purchase and/or install; thus, limiting their number can decrease construction costs. An sampling points of an ASD 544 may be disposed in the ductwork (e.g., in the return duct 540 or the supply duct 542) of one or more CRACs 502, advantageously allowing one ASD to monitor a large number of racks 504. It is noted that FIG. 15 shows potential locations of sampling points for an ASD 544 and does not imply that a specific number of ASDs is required. However, multiple ASDs may help increase sensitivity and/or response time. Similarly, other chemical sensors can be used in addition to or as an alternative to the ASD 544.

In the event that smoke, off-gases, or other indications of thermal degradation or overheating are detected in the ducts, temperature sensors on the racks 504 can be used by the rack smoke determiner 176 to localize the cause of the event. The rack 504 and/or area affected by the smoke event is likely to have elevated temperatures and/or temperature sensors that are no longer reporting measurements. Additionally or alternatively, an elevated cooling utilization index or a cooling utilization index that has recently changed may be indicative of the computer rack causing the overheating event. In some embodiments, the rack smoke determiner 176 is configured to determine a rack 504 that is causing an overheating event as described above. A number of mitigating actions can be taken by the action initiator to mitigate any loss associated with the smoke event. The overheating event may be a precursor to a fire, and it may still be possible to prevent a fire from starting. For example, the action initiator 180 may cause a second source of cooling to be provided to the computer rack. The rack 504 may include a provision for direct liquid cooling that can be pumped to the processors to exchange heat between the computers of the rack 504 and the chilled water system of a central (e.g., chiller) plant. Additionally or alternatively, the action initiator 180 may increase the air flow into the rack 504 to provide additional cooling. The action initiator 180 may also move computational load from a second computer in the second computer rack to a first computer in the computer rack. In some embodiments, a fire suppression system may be activated. For example, fire retardants can be deployed and/or a number of aisles may be isolated (e.g., no air may be provided to the isolated aisles), extinguishing any potential fire. Fire suppression may also include stopping computational tasks within any of the affected racks and/or closing off dampers to suffocate a fire if it exists. In some embodiments, the automated action performed depends on the detected chemicals and/or detection processes. For example, if the detection is indicative of smoke, fire suppression may be deployed, whereas if the detection is indicative of only overheating additional cooling may be deployed (e.g., liquid cooling or increased air flow rates). In some embodiments, the action initiator 180 can cause the location of the affected device to be displayed within a user interface, for example, overlaid on an overhead view, on a rendering from a BIM model, and/or on a floor plan of the data center.

In some embodiments, the affected computer racks may be determined by clustering temperature measurements associated with the computer racks. Any computer rack that has a temperature included in a cluster of elevated temperatures may be considered affected. Additionally or alternatively, clusters may be generated based on the temperature measurements and the location of the computer racks (e.g., racks in the same aisle, served by the same CRAC, etc.). Mitigation may be performed to all computer racks associated with the cluster.

### Configuration of Exemplary Embodiments

The construction and arrangement of the systems and methods as shown in the various exemplary embodiments are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.). For example, the position of elements can be reversed or otherwise varied and the nature or number of discrete elements or positions can be altered or varied. Accordingly, all such modifications are intended to be included within the scope of the present disclosure. The order or sequence of any process or method steps can be varied or re-sequenced according to alternative embodiments. Other substitutions, modifications, changes, and omissions can be made in the design, operating conditions and arrangement of the exemplary embodiments without departing from the scope of the present disclosure.

The present disclosure contemplates methods, systems and program products on any machine-readable media for accomplishing various operations. The embodiments of the present disclosure can be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

Although the figures show a specific order of method steps, the order of the steps may differ from what is depicted. Also two or more steps can be performed concurrently or with partial concurrence. Such variation will depend on the software and hardware systems chosen and on designer choice. All such variations are within the scope of the disclosure. Likewise, software implementations could be accomplished with standard programming techniques with rule based logic and other logic to accomplish the various connection steps, processing steps, comparison steps and decision steps.

What is claimed is:

1. A system for monitoring and controlling a data center, the system comprising:
a damper configured to adjust a resistance to air flowing through a computer rack; and
one or more memory devices having instructions stored thereon that, when executed by one or more processors, cause the one or more processors to perform operations comprising:
controlling an air temperature exiting the computer rack by adjusting the damper of the computer rack to a position based at least upon a measured value of the air temperature exiting the computer rack and a setpoint for the air temperature exiting the computer rack.

2. The system of claim 1, the operations further comprising estimating an amount of heat transferred to the air flowing through the computer rack using the measured value of the air temperature exiting the computer rack, wherein the position is based at least upon the estimated amount of heat transferred to the air.

3. The system of claim 2, the operations further comprising;
calculating a cooling utilization index based on the estimated amount of heat transferred to the air flowing through the computer rack, the cooling utilization index indicative of a fraction of cooling capacity provided to the computer rack to a total cooling capacity that can be provided to the computer rack; and
adjusting parameters of a control strategy for controlling the air temperature exiting the computer rack based on the cooling utilization index.

4. The system of claim 3, wherein the total cooling capacity that can be provided to the computer rack is based on at least one of:
a maximum air flow through the computer rack; or
a maximum outlet air temperature of the computer rack.

5. The system of claim 3, wherein the total cooling capacity that can be provided to the computer rack is based on at least one of:
a maximum outlet air temperature of the computer rack; or
a minimum outlet air temperature of HVAC equipment supplying cooled air to the computer rack.

6. The system of claim 1, wherein:
the damper is configured to open in response to a failure; or
the operations further comprise opening the damper in response to a failure.

7. The system of claim 1, wherein controlling the air temperature exiting the computer rack comprises executing a control algorithm with at least a proportional term and an integral term.

8. The system of claim 1, wherein controlling the air temperature exiting the computer rack comprises providing feedforward control based on an estimated amount of heat transferred to the air flowing through the computer rack.

9. The system of claim 8, wherein controlling the air temperature exiting the computer rack further comprises predicting the amount of heat transferred into the air flowing through the computer rack and providing the feedforward control based on the predicted amount of heat transferred.

10. A method for monitoring and controlling a data center, the method comprising:
estimating an amount of heat transferred to air flowing through a computer rack using a measured temperature of the air exiting the computer rack; and
controlling an air temperature exiting the computer rack by adjusting a damper to a position based at least upon the estimated amount of heat transferred to the air flowing through the computer rack.

11. The method of claim 10, further comprising:
calculating a cooling utilization index based on the estimated amount of heat transferred to the air flowing through the computer rack, the cooling utilization index indicative of a fraction of cooling capacity provided to the computer rack to a total cooling capacity that can be provided to the computer rack; and
adjusting parameters of a control strategy for controlling the air temperature exiting the computer rack based on the cooling utilization index.

12. The method of claim 11, wherein the total cooling capacity that can be provided to the computer rack is based on at least one of:
a maximum air flow through the computer rack; or
a maximum outlet air temperature of the computer rack.

13. The method of claim 11, wherein the total cooling capacity that can be provided to the computer rack is based on at least one of:
a maximum outlet air temperature of the computer rack; or
a minimum outlet air temperature of HVAC equipment supplying cooled air to the computer rack.

14. The method of claim 10, further comprising opening the damper in response to a failure.

15. The method of claim 10, wherein controlling the air temperature exiting the computer rack comprises executing a control algorithm with at least a proportional term and an integral term.

16. The method of claim 10, further comprising selecting a setpoint for the air temperature exiting the computer rack or an air flow rate through the computer rack based on a health index of a computing device in the computer rack.

17. The method of claim 16, wherein the setpoint is selected below a threshold temperature at which the health index of the computing device no longer decreases.

18. A cooling system for a computer rack comprising:
a damper configured to attach to the computer rack and operable to adjust a resistance to air flowing through the computer rack;
a temperature sensor configured to attach to the computer rack and measure the temperature of the air flowing through the computer rack as the air exits the computer rack; and
one or more memory devices having instructions stored thereon that, when executed by one or more processors, cause the one or more processors to perform operations comprising:
controlling an air temperature exiting the computer rack by adjusting the damper to a position based at least on a measurement from the temperature sensor.

19. The cooling system of claim 18, the operations further comprising calculating a cooling utilization index based at least on a measurement the temperature of the air flowing through the computer rack as it exits the computer rack, the cooling utilization index indicative of a fraction of cooling provided to the computer rack to a cooling capacity available to the computer rack.

20. The cooling system of claim 18, the operations further comprising calculating a server health index for one or more computers installed in the computer rack based on an integration over time when: (i) a temperature of the one or more computers is greater than a temperature threshold, (ii) a CPU usage of the one or more computers is greater than a CPU usage threshold, or (iii) a RAM usage of the one or more computers is greater than a RAM usage threshold.
